(19) United States
(12) Patent Application Publication
(10) Pub. No.: US 2025/0022920 A1
(43) Pub. Date: Jan. 16, 2025

(54) SIC SEMICONDUCTOR DEVICE

(71) Applicant: ROHM CO., LTD., Kyoto-shi (JP)

(72) Inventors: Keisuke NAGAYA, Kyoto-shi (JP); Yuki NAKANO, Kyoto-shi (JP); Kenji YAMAMOTO, Kyoto-shi (JP); Seigo MORI, Kyoto-shi (JP)

(73) Assignee: ROHM CO., LTD., Kyoto-shi (JP)

(21) Appl. No.: 18/901,248

(22) Filed: Sep. 30, 2024

Related U.S. Application Data
(63) Continuation of application No. PCT/JP2023/006639, filed on Feb. 24, 2023.

(30) Foreign Application Priority Data
Mar. 31, 2022 (JP) 2022-061145

(51) Int. Cl. H01L 29/16; H01L 29/08; H01L 29/423; H01L 29/78

(52) U.S. Cl. CPC H01L 29/1608; H01L 29/086; H01L 29/4236; H01L 29/7813

(57) ABSTRACT

An SiC semiconductor device includes a chip that includes an SiC monocrystal and has a main surface, a trench structure that has a side wall and a bottom wall and is formed in the main surface, and a contact region of a first conductivity type that includes a first region formed in a region along the side wall in a surface layer portion of the main surface and a second region formed in a region along the bottom wall inside the chip and having an impurity concentration lower than an impurity concentration of the first region.

### CROSS-REFERENCE TO RELATED APPLICATIONS

The present application is a bypass continuation of International Patent Application No. PCT/JP2023/006639 filed on Feb. 24, 2023, claiming the benefit of priority based on Japanese Patent Application No. 2022-061145 filed on Mar. 31, 2022, and the entire disclosures of those applications are hereby incorporated herein by reference.

### BACKGROUND

### 1. Field of the Disclosure

The present disclosure relates to an SiC semiconductor device.

### 2. Description of the Related Art

US2014/0145209A1 discloses, in FIG. 8, an SiC vertical power MOSFET that includes an n-type drift layer, a trench structure formed in the n-type drift layer, and a high-concentration p base region formed in a region inside the n-type drift layer along a bottom wall of the trench structure.

### BRIEF DESCRIPTION OF THE DRAWINGS

FIG. 1 is a plan view showing an SiC semiconductor device according to a first embodiment.

FIG. 2 is a plan view showing a layout of a first main surface.

FIG. 3 is a cross sectional view taken along line III-III shown in FIG. 2.

FIG. 4 is an enlarged plan view showing a main portion of the first main surface.

FIG. 5 is an enlarged plan view showing another main portion of the first main surface.

FIG. 6 is a cross sectional view taken along line VI-VI shown in FIG. 4.

FIG. 7 is a cross sectional view taken along line VII-VII shown in FIG. 5.

FIG. 8 is an enlarged plan view showing a region including second trench structures and a third trench structure.

FIG. 9 is a cross sectional view taken along line IX-IX shown in FIG. 8.

FIG. 10 is a cross sectional view taken along line X-X shown in FIG. 8.

FIG. 11 is a cross sectional view taken along line XI-XI shown in FIG. 8.

FIG. 12 is a cross sectional view taken along line XII-XII shown in FIG. 8.

FIG. 13 is a cross sectional view taken along line XIII-XIII shown in FIG. 8.

FIG. 14 is a cross sectional view taken along line XIV-XIV shown in FIG. 8.

FIG. 15 is a cross sectional view taken along line XV-XV shown in FIG. 8.

FIG. 16A is an enlarged cross sectional view showing an arrangement where a region including a second trench structure and a contact region is cut in an m-axis direction.

FIG. 16B is an enlarged cross sectional view showing an arrangement where the region including the second trench structure and the contact region is cut in an a-axis direction.

FIG. 17 is a cross sectional view showing a peripheral edge portion of a chip.

FIG. 18 is a plan view showing an SiC semiconductor device according to a second embodiment.

FIG. 19 is a plan view showing an SiC semiconductor device according to a third embodiment.

FIG. 20 is a plan view showing an SiC semiconductor device according to a fourth embodiment.

FIG. 21 is a plan view showing an SiC semiconductor device according to a fifth embodiment.

FIG. 22 is a plan view showing an SiC semiconductor device according to a sixth embodiment.

FIG. 23 is a plan view showing an SiC semiconductor device according to a seventh embodiment.

FIG. 24 is a plan view showing an SiC semiconductor device according to a eighth embodiment.

FIG. 25 is a plan view showing an SiC semiconductor device according to a ninth embodiment.

FIG. 26 is a cross sectional view taken along line XXVI-XXVI shown in FIG. 25.

FIG. 27 is a cross sectional view taken along line XXVII-XXVII shown in FIG. 25.

FIG. 28A is an enlarged cross sectional view showing the arrangement where the region including the second trench structure and the contact region is cut in them-axis direction.

FIG. 28B is an enlarged cross sectional view showing the arrangement where the region including the second trench structure and the contact region is cut in the a-axis direction.

FIG. 29 is a plan view showing an SiC semiconductor device according to a tenth embodiment.

FIG. 30 is a plan view showing an SiC semiconductor device according to an eleventh embodiment.

FIG. 31 is a plan view showing an SiC semiconductor device according to a twelfth embodiment.

FIG. 32 is a plan view showing an SiC semiconductor device according to a thirteenth embodiment.

FIG. 33 is a plan view showing an SiC semiconductor device according to a fourteenth embodiment.

FIG. 34 is a plan view showing an SiC semiconductor device according to a fifteenth embodiment.

FIG. 35 is a cross sectional view showing a modification example of the second trench structures.

### DETAILED DESCRIPTION OF THE PREFERRED EMBODIMENTS

Hereinafter, embodiments shall be described in detail with reference to attached drawings. The attached drawings are schematic views and are not strictly illustrated, and scales and the like thereof do not always match. Also, identical reference signs are given to corresponding structures among the attached drawings, and duplicate descriptions thereof shall be omitted or simplified. For the structures whose description has been omitted or simplified, the description given before the omission or simplification shall apply.

When the wording “substantially equal” is used in a description in which a comparison target is present, the wording includes a numerical value (form) equal to a numerical value (form) of the comparison target and also includes numerical errors (form errors) in a range of ±10% on a basis of the numerical value (form) of the comparison target. Although the wordings “first,” “second,” “third,” etc., are used with the embodiments, these are symbols attached to names of respective structures in order to clarify the order of description and are not attached with an intention of restricting the names of the respective structures.

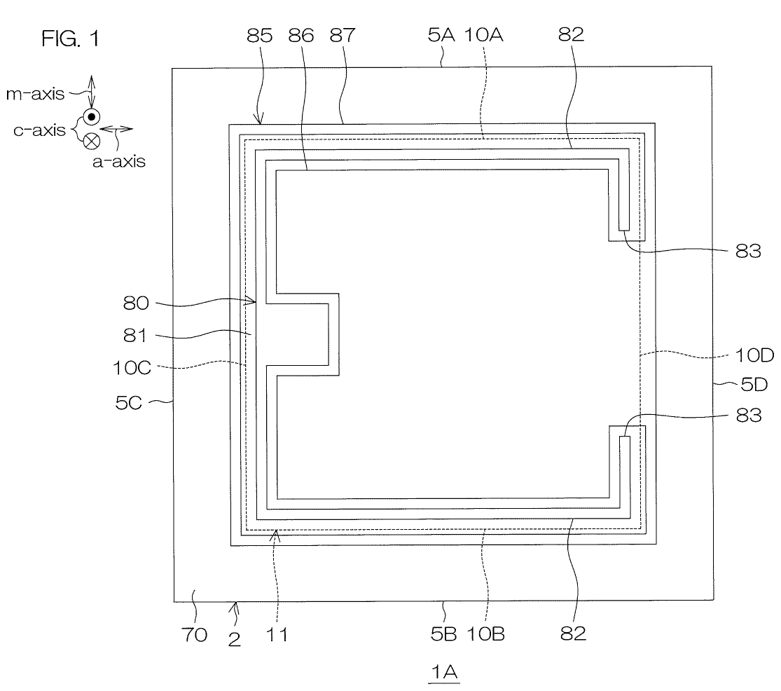

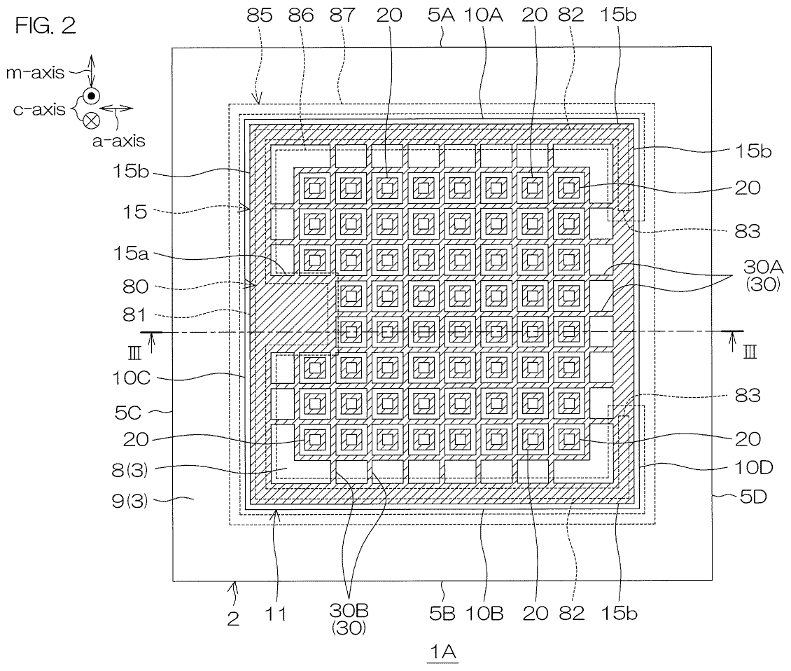

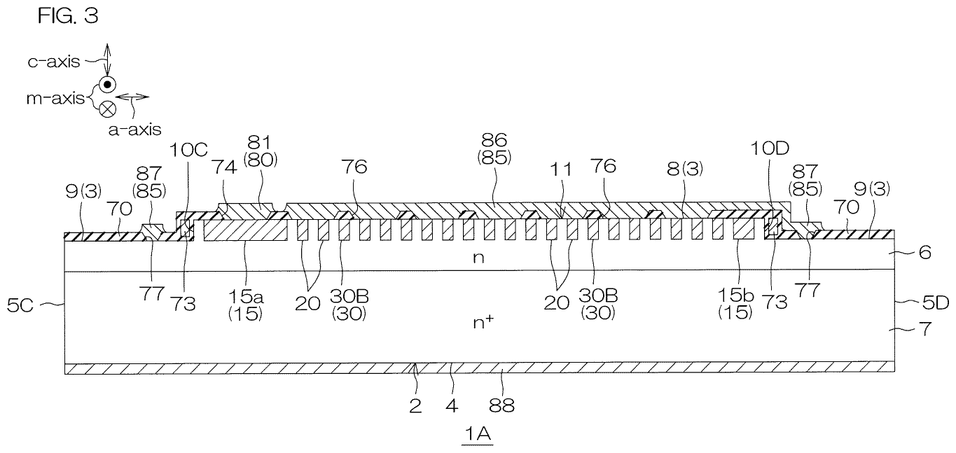

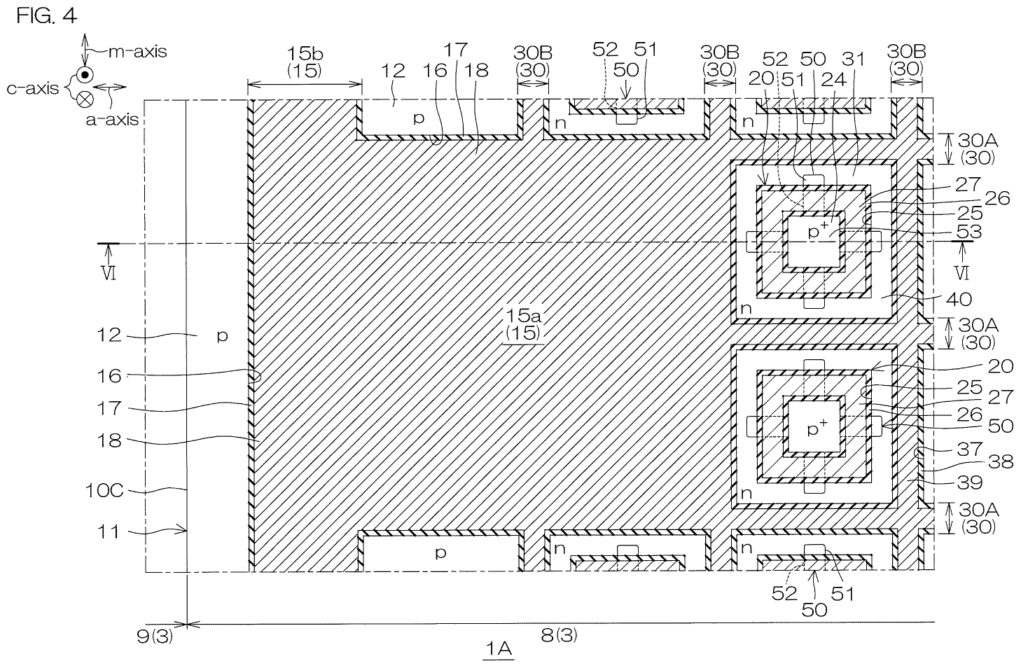

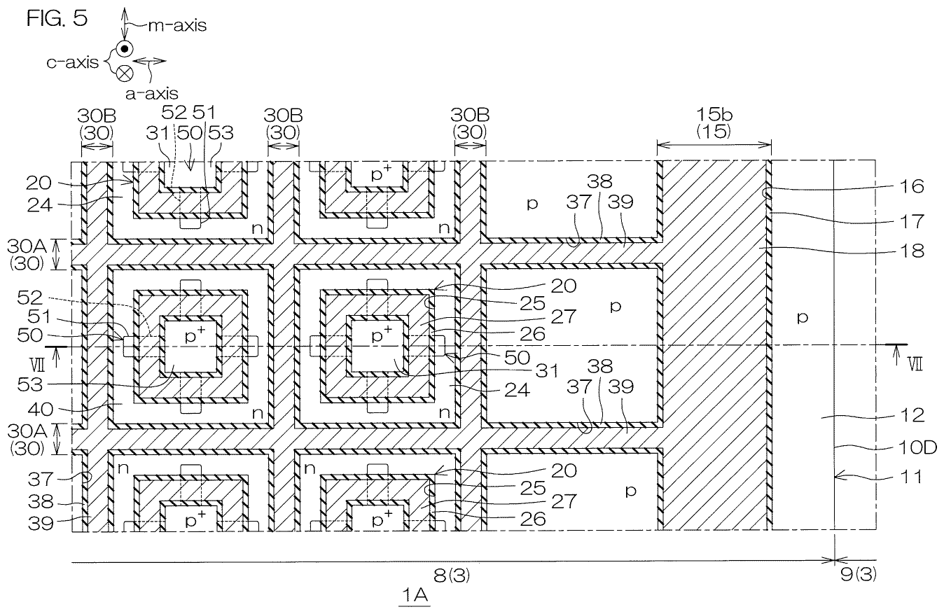

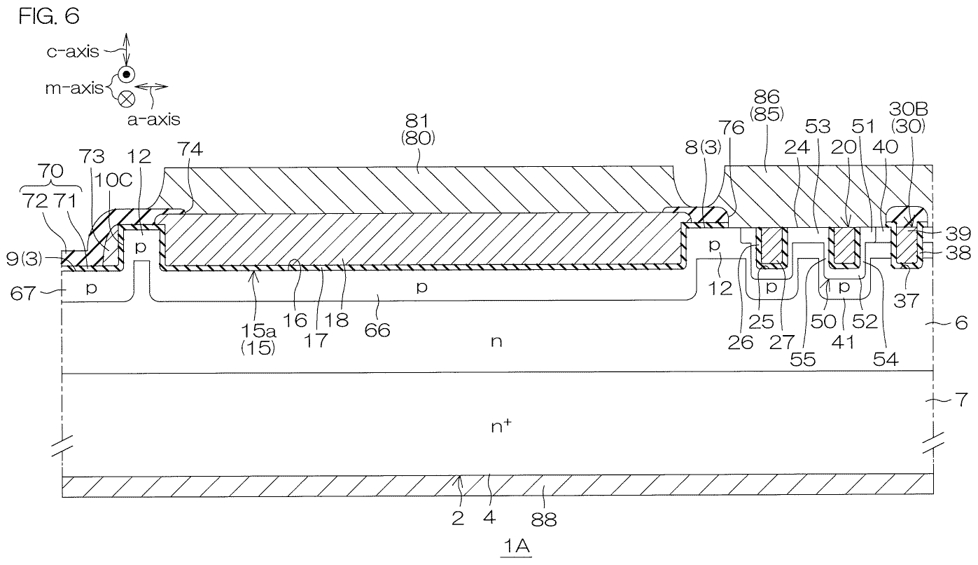

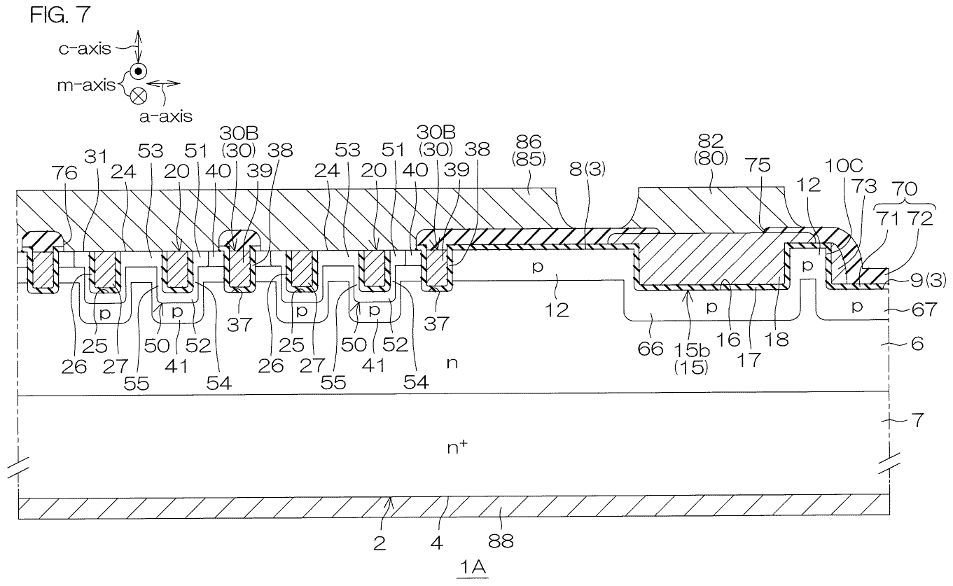

FIG. 1 is a plan view showing an SiC semiconductor device 1A according to a first embodiment. FIG. 2 is a plan view showing a layout of a first main surface 3. FIG. 3 is a cross sectional view taken along line III-III shown in FIG. 2. FIG. 4 is an enlarged plan view showing a main portion of the first main surface 3. FIG. 5 is an enlarged plan view showing another main portion of the first main surface 3. FIG. 6 is a cross sectional view taken along line VI-VI shown in FIG. 4. FIG. 7 is a cross sectional view taken along line VII-VII shown in FIG. 5.

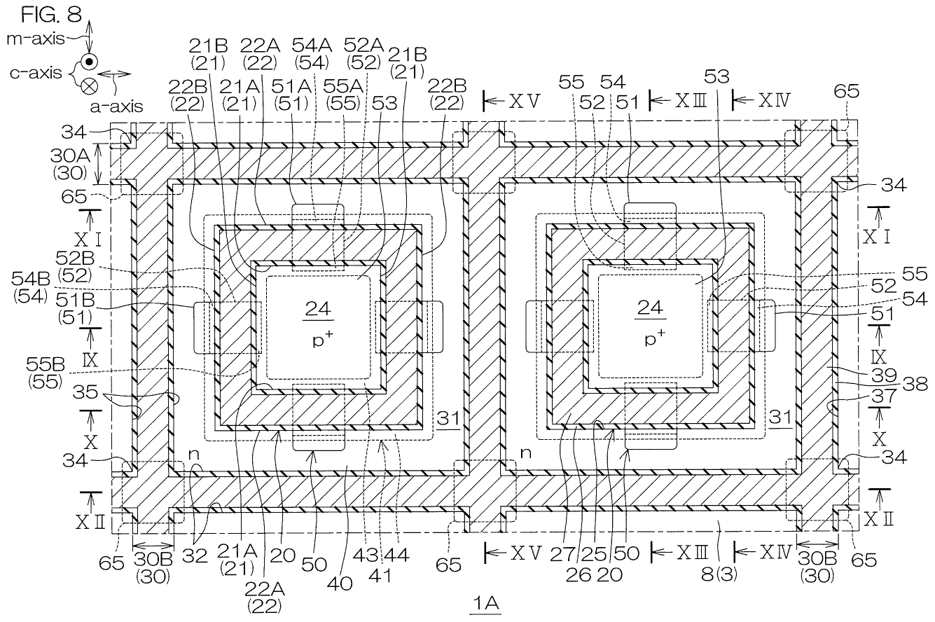

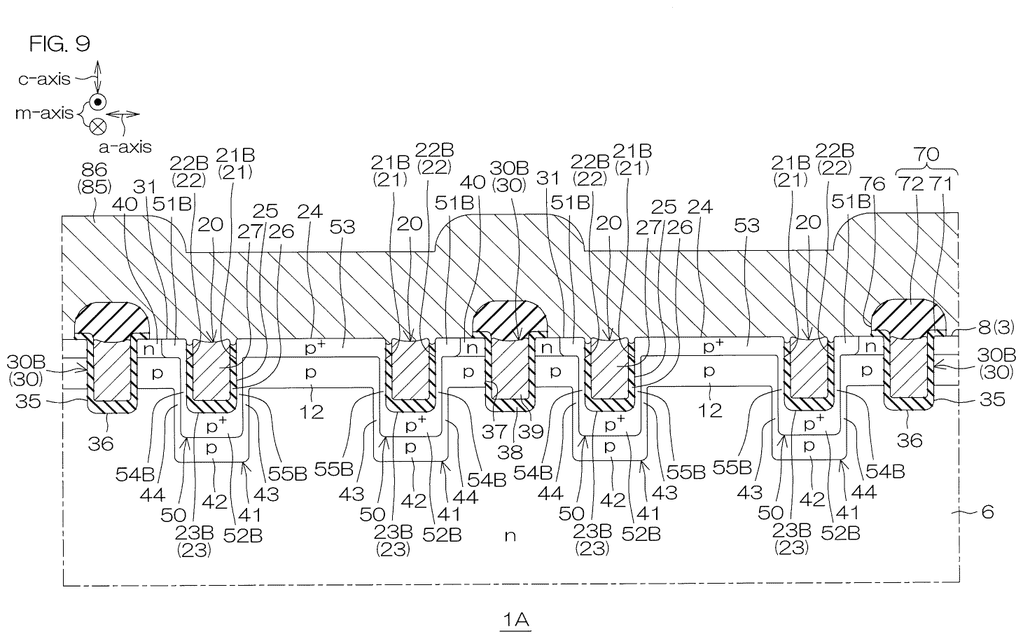

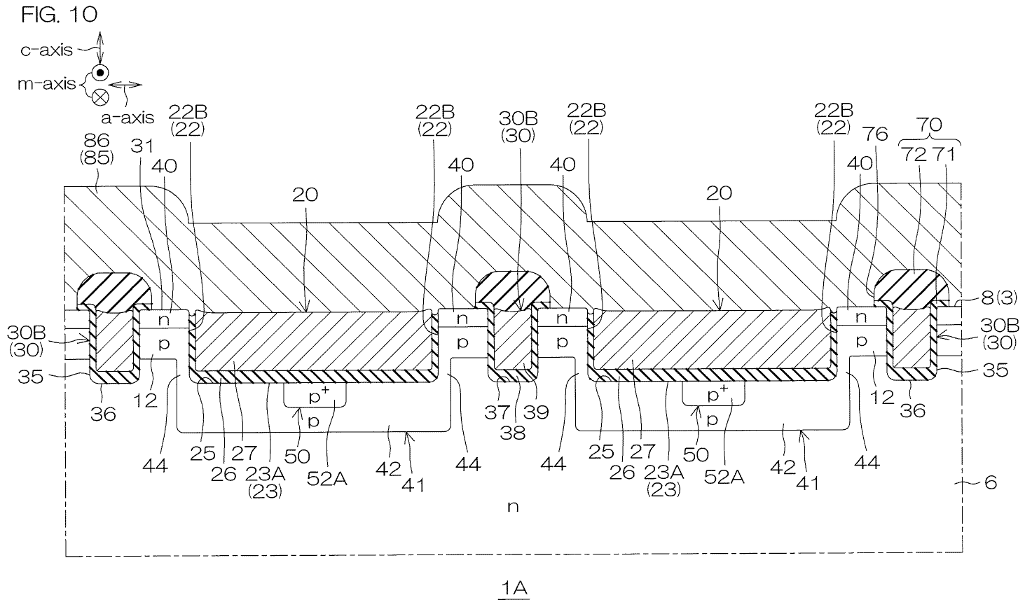

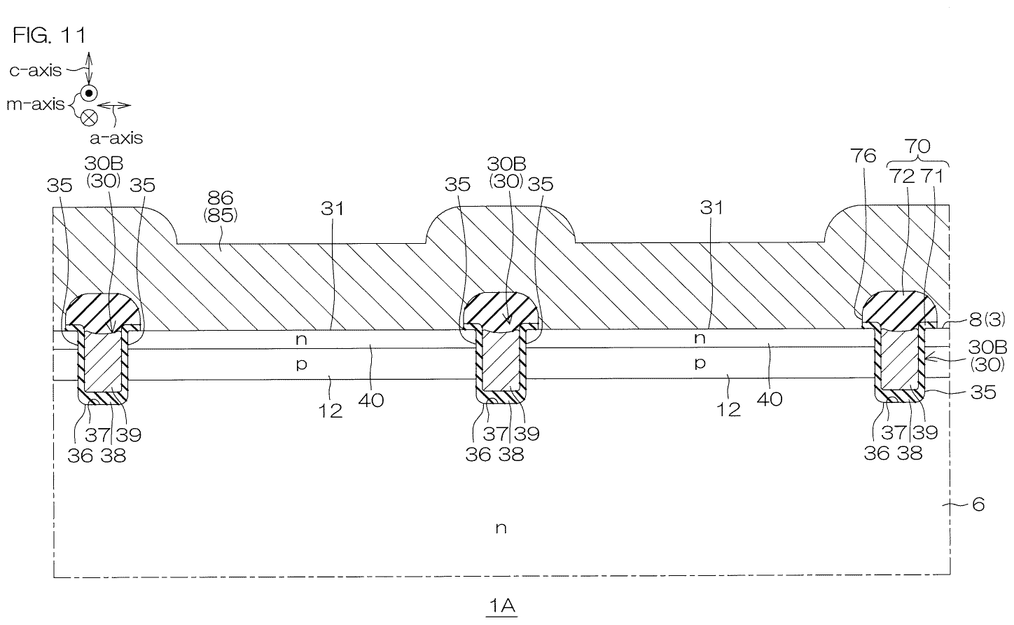

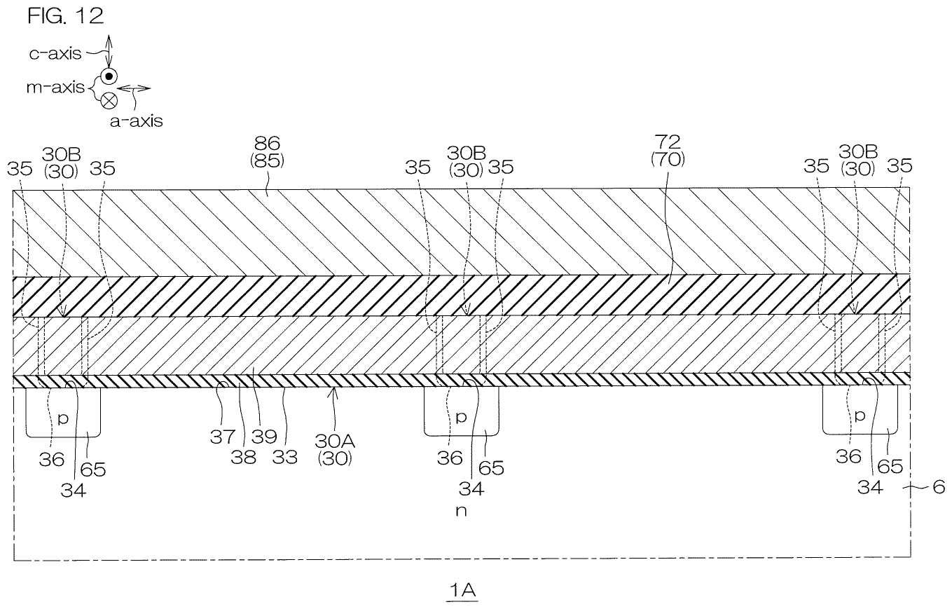

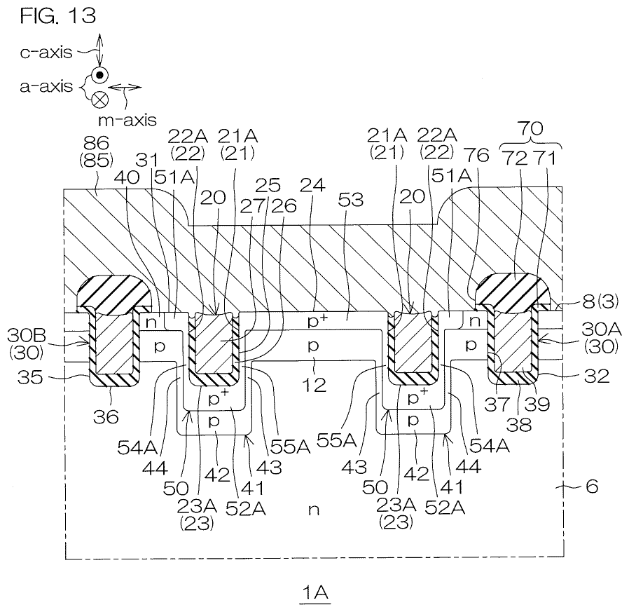

FIG. 8 is an enlarged plan view showing a region including second trench structures 20 and a third trench structure 30. FIG. 9 is a cross sectional view taken along line IX-IX shown in FIG. 8. FIG. 10 is a cross sectional view taken along line X-X shown in FIG. 8. FIG. 11 is a cross sectional view taken along line XI-XI shown in FIG. 8. FIG. 12 is a cross sectional view taken along line XII-XII shown in FIG. 8. FIG. 13 is a cross sectional view taken along line XIII-XIII shown in FIG. 8.

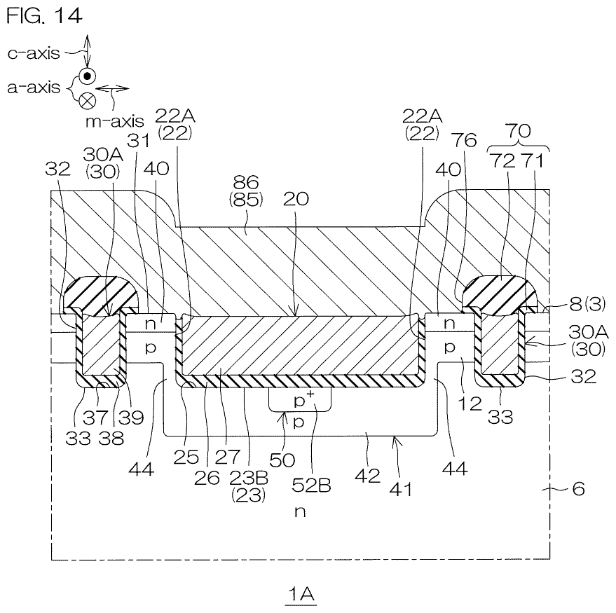

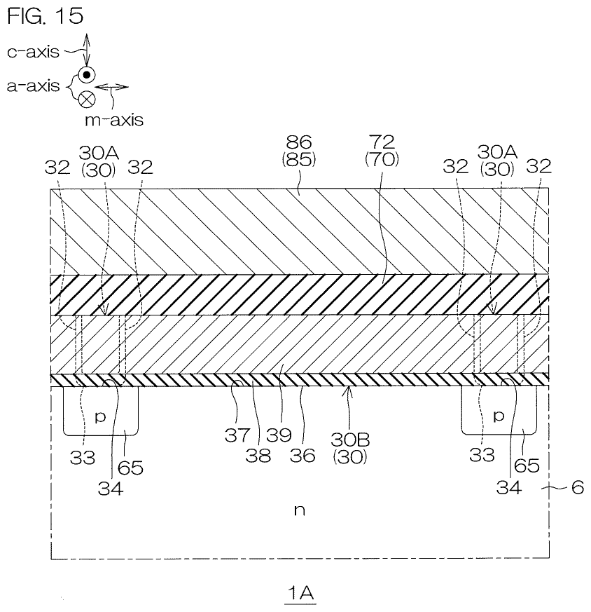

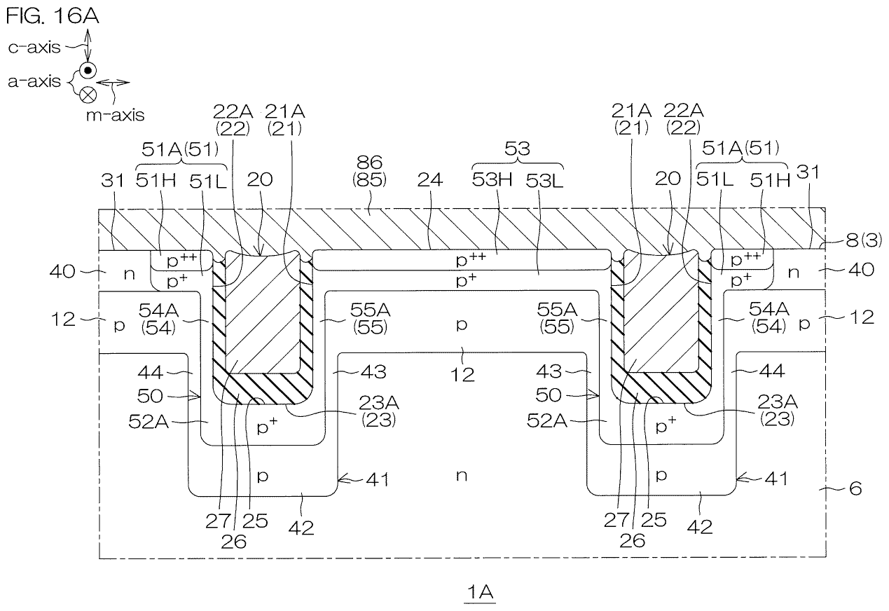

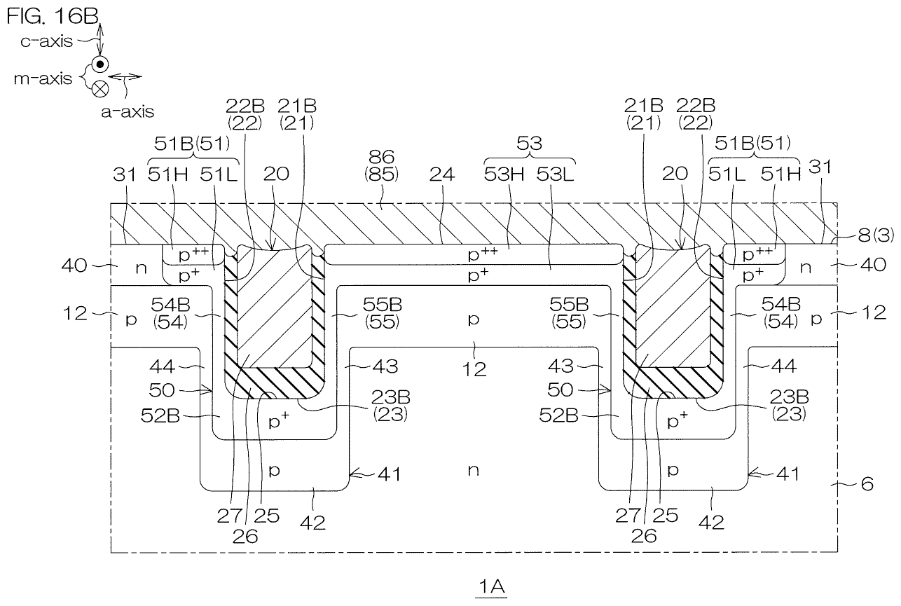

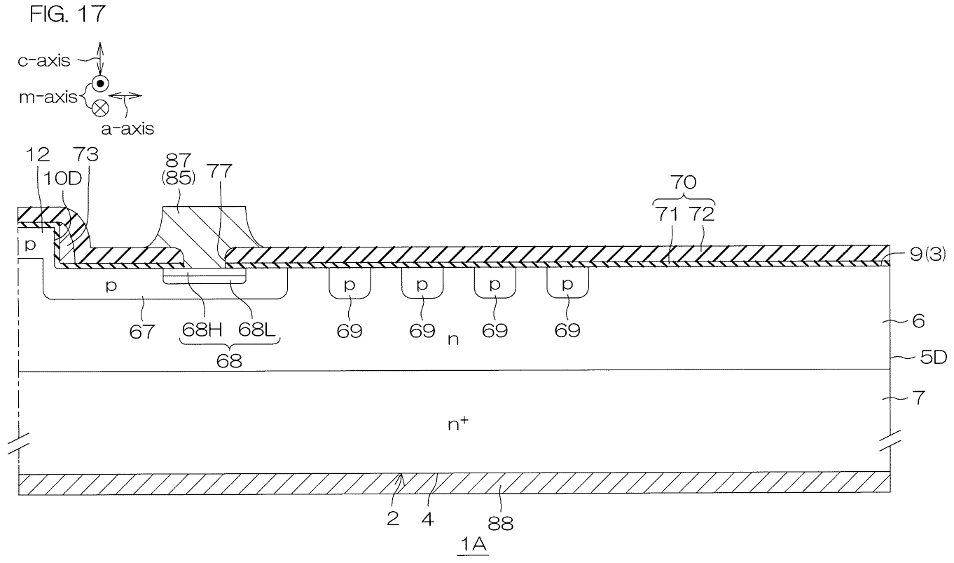

FIG. 14 is a cross sectional view taken along line XIV-XIV shown in FIG. 8. FIG. 15 is a cross sectional view taken along line XV-XV shown in FIG. 8. FIG. 16A is an enlarged cross sectional view showing an arrangement where a region including the second trench structure 20 and a contact region 50 is cut in an m-axis direction. FIG. 16B is an enlarged cross sectional view showing an arrangement where the region including the second trench structure 20 and the contact region 50 is cut in an a-axis direction. FIG. 17 is a cross sectional view showing a peripheral edge portion of a chip 2.

With reference to FIG. 1 to FIG. 17, the SiC semiconductor device 1A is an SiC semiconductor switching device that includes an SiC-MISFET (metal insulator semiconductor field effect transistor). In this embodiment, the SiC semiconductor device 1A includes the chip 2 including an SiC monocrystal that is a hexagonal crystal and formed in a hexahedral shape (specifically, a rectangular parallelepiped shape). The SiC monocrystal that is a hexagonal crystal has multiple polytypes including a 2H (hexagonal)-SiC monocrystal, a 4H-SiC monocrystal, a 6H-SiC monocrystal, etc. In this embodiment, an example in which the chip 2 includes the 4H-SiC monocrystal is to be given, but the chip 2 may include another polytype instead.

The chip 2 has a first main surface 3 on one side, a second main surface 4 on the other side, and first to fourth side surfaces 5A to 5D connecting the first main surface 3 and the second main surface 4. The first main surface 3 and the second main surface 4 are formed by c-planes of the SiC monocrystal. Specifically, the first main surface 3 is formed by a silicon plane ((0001) plane) of the SiC monocrystal and the second main surface 4 is formed by a carbon plane ((000-1) plane) of the SiC monocrystal.

The first main surface 3 and the second main surface 4 are each formed in a quadrangle shape in plan view as viewed from a c-axis direction ([0001] direction) of the SiC monocrystal (hereinafter, simply referred to as “plan view”). The c-axis direction is a normal direction of the c-plane. The c-axis direction is also a thickness direction of the chip 2. The first main surface 3 and the second main surface 4 may each have an off angle inclined in a predetermined off direction at a predetermined angle with respect to the c-plane.

The off direction is preferably an a-axis direction ([11-20] direction) of the SiC monocrystal. The off angle may exceed 0° and be not more than 10°. The off angle is preferably not more than 5°. When the first main surface 3 (second main surface 4) has the off angle, the c-axis is inclined by just the off angle in the off direction with respect to a normal to the first main surface 3 (second main surface 4). In the attached drawings, the c-axis that extends along the normal to the first main surface 3 (second main surface 4) is illustrated for convenience. The second main surface 4 may consist of a ground surface with grinding marks, or may consist of a smooth surface without a grinding mark.

The first side surface 5A and the second side surface 5B extend in the a-axis direction of the SiC monocrystal and are opposed in an m-axis direction ([1-100] direction) of the SiC monocrystal. That is, the first side surface 5A and the second side surface 5B are formed by m-planes ((1-100) planes) of the SiC monocrystal. The third side surface 5C and the fourth side surface 5D extend in the m-axis direction of the SiC monocrystal and are opposed in the a-axis direction of the SiC monocrystal.

That is, the third side surface 5C and the fourth side surface 5D are formed by a-planes ((11-20) planes) of the SiC monocrystal. The first to fourth side surfaces 5A to 5D may each consist of a ground surface with grinding marks, or may each consist of a smooth surface without a grinding mark. The c-axis direction may be referred to as a “thickness direction,” the a-axis direction may be referred to as a “first direction,” and the m-axis direction may be referred to as a “second direction.”

The chip 2 may have a thickness of not less than 5 μm and not more than 350 μm. The thickness of the chip 2 may be set to a value belonging to any one range among not less than 5 μm and not more than 50 μm, not less than 50 μm and not more than 100 μm, not less than 100 μm and not more than 150 μm, not less than 150 μm and not more than 200 μm, not less than 200 μm and not more than 250 μm, not less than 250 μm and not more than 300 μm, and not less than 300 μm and not more than 350 μm. The thickness of the chip 2 is preferably not more than 150 μm.

The first to fourth side surfaces 5A to 5D may each have a length of not less than 0.5 mm and not more than 20 mm in plan view. The length of each of the first to fourth side surfaces 5A to 5D may be set to a value belonging to any one range among not less than 0.5 mm and not more than 5 mm, not less than 5 mm and not more than 10 mm, not less than 10 mm and not more than 15 mm, and not less than 15 mm and not more than 20 mm. The length of each of the first to fourth side surfaces 5A to 5D is preferably not less than 5 mm.

The SiC semiconductor device 1A includes a first semiconductor region 6 of an n-type that is formed in a region (surface layer portion) inside the chip 2 at the first main surface 3 side. The first semiconductor region 6 may have an n-type impurity concentration (maximum value) of not less than 1.0×10¹⁵ cm⁻³ and not more than 1.0×10¹⁷ cm⁻³. The first semiconductor region 6 is formed in a layered shape extending along the first main surface 3 and is exposed from the first main surface 3 and the first to fourth side surfaces 5A to 5D.

In this embodiment, the first semiconductor region 6 consists of an SiC epitaxial layer. The first semiconductor region 6 may have a thickness of not less than 1 μm and not more than 50 μm. The thickness of the first semiconductor region 6 is preferably not less than 5 μm and not more than 30 μm. The thickness of the first semiconductor region 6 is particularly preferably not more than 25 μm.

The SiC semiconductor device 1A includes a second semiconductor region 7 of the n-type that is formed in a region (surface layer portion) inside the chip 2 at the second main surface 4 side. The second semiconductor region 7 is formed in a layered shape extending along the second main surface 4 and is exposed from the second main surface 4 and the first to fourth side surfaces 5A to 5D. The second semiconductor region 7 has an n-type impurity concentration higher than that of the first semiconductor region 6 and is electrically connected to the first semiconductor region 6.

The second semiconductor region 7 may have an n-type impurity concentration (maximum value) of not less than 1.0×10¹⁸ cm⁻³ and not more than 1.0×10²¹ cm⁻³. In this embodiment, the second semiconductor region 7 consists of an SiC substrate. That is, the chip 2 has a laminated structure including the SiC substrate and the SiC epitaxial layer.

The second semiconductor region 7 may have a thickness of not less than 1 μm and not more than 350 μm. The thickness of the second semiconductor region 7 is preferably not less than 5 μm and not more than 50 μm. The thickness of the second semiconductor region 7 is particularly preferably not less than 5 μm and not more than 20 μm. The thickness of the second semiconductor region 7 is preferably not less than 10 μm. The thickness of the second semiconductor region 7 may exceed the thickness of the first semiconductor region 6. The thickness of the second semiconductor region 7 may be less than the thickness of the first semiconductor region 6.

The SiC semiconductor device 1A includes an active surface 8, an outer surface 9, and first to fourth connecting surfaces 10A to 10D that are formed in the first main surface 3. The active surface 8, the outer surface 9, and the first to fourth connecting surfaces 10A to 10D demarcate an active mesa 11 in the first main surface 3. The active surface 8 may be referred to as a “first surface portion,” the outer surface 9 may be referred to as a “second surface portion,” and the first to fourth connecting surfaces 10A to 10D may be referred to as “connecting surface portions.” The active surface 8, the outer surface 9, and the first to fourth connecting surfaces 10A to 10D (that is, the active mesa 11) may be considered as components of the chip 2 (first main surface 3).

The active surface 8 is formed at an interval inward from a peripheral edge of the first main surface 3 (first to fourth side surfaces 5A to 5D). The active surface 8 has a flat surface formed by a c-plane (Si plane). In this embodiment, the active surface 8 is formed in a quadrangle shape having four sides parallel to the first to fourth side surfaces 5A to 5D in plan view.

The outer surface 9 is positioned outside the active surface 8 and is recessed in the thickness direction of the chip 2 (toward the second main surface 4 side) from the active surface 8. Specifically, the outer surface 9 is recessed to a depth less than the thickness of the first semiconductor region 6 such as to expose the first semiconductor region 6. The outer surface 9 extends in a band shape along the active surface 8 and is formed in an annular shape (specifically, a quadrangle annular shape) surrounding the active surface 8 in plan view. The outer surface 9 has a flat surface formed by a c-plane (Si plane) and is formed substantially parallel to the active surface 8. The outer surface 9 is continuous to the first to fourth side surfaces 5A to 5D.

The first to fourth connecting surfaces 10A to 10D extend in the c-axis direction and connect the active surface 8 and the outer surface 9. The first connecting surface 10A is positioned at the first side surface 5A side, the second connecting surface 10B is positioned at the second side surface 5B side, the third connecting surface 10C is positioned at the third side surface 5C side, and the fourth connecting surface 10D is positioned at the fourth side surface 5D side.

The first connecting surface 10A and the second connecting surface 10B extend in the a-axis direction and are opposed in the m-axis direction in plan view. That is, the first side surface 5A and the second side surface 5B are formed by m-planes. The third connecting surface 10C and the fourth connecting surface 10D extend in the m-axis direction and are opposed in the a-axis direction in plan view. That is, the third side surface 5C and the fourth side surface 5D are formed by a-planes.

The first to fourth connecting surfaces 10A to 10D may extend substantially vertically between the active surface 8 and the outer surface 9 such as to demarcate the active mesa 11 of a quadrangle columnar shape. The first to fourth connecting surfaces 10A to 10D may be downwardly inclined from the active surface 8 toward the outer surface 9 such as to demarcate the active mesa 11 of a quadrangle pyramid shape instead. The SiC semiconductor device 1A thus includes the active mesa 11 that is demarcated in projecting shape in the first semiconductor region 6 at the first main surface 3. The active mesa 11 is formed only in the first semiconductor region 6 and is not formed in the second semiconductor region 7.

The SiC semiconductor device 1A includes a body region 12 of a p-type that is formed in a surface layer portion of the active surface 8. The body region 12 may have a p-type impurity concentration (maximum value) of not less than 1.0×10¹⁶ cm⁻³ and not more than 1.0×10¹⁹ cm⁻³. The body region 12 is formed in a surface layer portion of the first semiconductor region 6 at an interval to the active surface 8 side from a bottom portion of the first semiconductor region 6 and opposes the second semiconductor region 7 with a portion of the first semiconductor region 6 interposed therebetween. The body region 12 is formed in a layered shape extending along the active surface 8. The body region 12 may be exposed from the first to fourth connecting surfaces 10A to 10D.

The SiC semiconductor device 1A includes a first trench structure 15 that is formed in the active surface 8. A gate potential is to be applied to the first trench structure 15. The first trench structure 15 may be referred to as a “trench gate wiring structure.” The first trench structure 15 penetrates through the body region 12 and reaches the first semiconductor region 6. The first trench structure 15 is formed at an interval to the active surface 8 side from the bottom portion of the first semiconductor region 6 and opposes the second semiconductor region 7 with a portion of the first semiconductor region 6 interposed therebetween. The first trench structure 15 preferably has a depth substantially equal to the depth of the outer surface 9.

The first trench structure 15 is formed in a peripheral edge portion of the active surface 8 at an interval from a peripheral edge of the active surface 8 (first to fourth connecting surfaces 10A to 10D) and extends in a band shape such as to surround an inner portion of the active surface 8. In this embodiment, the first trench structure 15 is formed in an annular shape (specifically, a quadrangle annular shape) extending along the first to fourth connecting surfaces 10A to 10D.

The first trench structure 15 includes a pad portion 15a and a line portion 15b. The pad portion 15a is arranged at a peripheral edge portion of the active surface 8 at an interval from a central portion of the third connecting surface 10C and is formed in a quadrangle shape in plan view. The line portion 15b is drawn out in a band shape from the pad portion 15a and extends along the peripheral edge of the active surface 8 such as to surround the inner portion of the active surface 8. The line portion 15b is formed to be narrower in width than the pad portion 15a.

The first trench structure 15 includes a first trench 16, a first insulating film 17, and a first embedded electrode 18. The first trench 16 may be referred to as a “wiring trench,” the first insulating film 17 may be referred to as a “wiring insulating film,” and the first embedded electrode 18 may be referred to as a “wiring embedded electrode.” The first trench 16 is formed in the active surface 8 and demarcates a wall surface of the first trench structure 15.

The first insulating film 17 covers a wall surface of the first trench 16 as a film. The first insulating film 17 may include at least one among a silicon oxide film, a silicon nitride film, and a silicon oxynitride film. In this embodiment, the first insulating film 17 has a single layer structure consisting of the silicon oxide film. The first insulating film 17 particularly preferably includes the silicon oxide film that consists of an oxide of the chip 2.

The first embedded electrode 18 is embedded in the first trench 16 with the first insulating film 17 interposed therebetween. The first embedded electrode 18 may project further upward than the first main surface 3. The first embedded electrode 18 may have a portion that is drawn out onto the first main surface 3 from the first trench 16. The first embedded electrode 18 may contain a conductive polysilicon.

The SiC semiconductor device 1A includes a plurality of second trench structures 20 that are formed in the active surface 8. A source potential is to be applied to the plurality of second trench structures 20. The second trench structures 20 may be referred to as “trench source structures.” The plurality of second trench structures 20 are formed in the inner portion of the active surface 8 at intervals from the first trench structure 15. The plurality of second trench structures 20 penetrate through the body region 12 and reach the first semiconductor region 6.

The plurality of second trench structures 20 are formed at an interval to the active surface 8 side from the bottom portion of the first semiconductor region 6 and oppose the second semiconductor region 7 with portions of the first semiconductor region 6 interposed therebetween. The plurality of second trench structures 20 preferably have a depth substantially equal to the depth of the first trench structure 15. The plurality of second trench structures 20 preferably have a depth substantially equal to the depth of the outer surface 9. The second trench structures 20 are each preferably formed to be narrower in width than the first trench structure 15.

The plurality of second trench structures 20 are arrayed at intervals in the a-axis direction and the m-axis direction in plan view. The plurality of second trench structures 20 may be arrayed in a matrix pattern in plan view. In this case, the SiC semiconductor device 1A includes the plurality of second trench structures 20 that are arrayed at intervals such as to oppose each other in the a-axis direction and the m-axis direction.

The plurality of second trench structures 20 may be arrayed in a staggered manner in plan view. In this case, the SiC semiconductor device 1A may include a plurality of groups that are arrayed at intervals in the m-axis direction and each include a plurality of second trench structures 20 that are arrayed at intervals in a single column in the a-axis direction. In this case, the plurality of second trench structures 20 belonging to one group are shifted in the a-axis direction such as to oppose regions (for example, intermediate regions) between the plurality of second trench structures 20 belonging to another group in the m-axis direction.

As a matter of course, the SiC semiconductor device 1A may include a plurality of groups that are arrayed at intervals in the a-axis direction and each include a plurality of second trench structures 20 that are arrayed at intervals in a single column in the m-axis direction. In this case, the plurality of second trench structures 20 belonging to one group are shifted in the m-axis direction such as to oppose regions (for example, intermediate regions) between the plurality of second trench structures 20 belonging to another group in the a-axis direction.

Hereinafter, the arrangement of the single second trench structure 20 shall be described. With reference to FIG. 8 to FIG. 15, the second trench structure 20 is formed in an annular shape (specifically, a quadrangle annular shape) extending in the a-axis direction and the m-axis direction in plan view in this embodiment. The second trench structure 20 includes an inner side wall 21, an outer side wall 22, and a bottom wall 23.

The inner side wall 21 forms an inner edge of the second trench structure 20 and is formed in a quadrangle shape extending in the a-axis direction and the m-axis direction in plan view. Specifically, the inner side wall 21 includes a pair of first inner side walls 21A and a pair of second inner side walls 21B.

The pair of first inner side walls 21A extend in the a-axis direction and are opposed in the m-axis direction. That is, the pair of first inner side walls 21A are demarcated by m-planes. The pair of second inner side walls 21B extend in the m-axis direction such as to be connected to the pair of first inner side walls 21A and are opposed in the a-axis direction. That is, the pair of second inner side walls 21B are demarcated by a-planes. The inner side wall 21 demarcates a first mesa portion 24 of a quadrangle shape in the active surface 8.

The outer side wall 22 forms an outer edge of the second trench structure 20 and surrounds the inner side wall 21 in plan view. The outer side wall 22 is formed in a quadrangle shape extending in the a-axis direction and the m-axis direction. Specifically, the outer side wall 22 includes a pair of first outer side walls 22A and a pair of second outer side walls 22B.

The pair of first outer side walls 22A extend in the a-axis direction and are opposed in the m-axis direction. That is, the pair of first outer side walls 22A are demarcated by m-planes. The pair of second outer side walls 22B extend in the m-axis direction such as to be connected to the pair of first outer side walls 22A and are opposed in the a-axis direction. That is, the pair of second outer side walls 22B are demarcated by a-planes.

The bottom wall 23 connects the inner side wall 21 and the outer side wall 22 and is formed in an annular shape (specifically, a quadrangle annular shape) extending in the a-axis direction and the m-axis direction in plan view. Specifically, the bottom wall 23 includes a pair of first bottom walls 23A and a pair of second bottom walls 23B.

The pair of first bottom walls 23A extend in band shapes in the a-axis direction. The pair of second bottom walls 23B extend in band shapes in the m-axis direction such as to be connected to the pair of first bottom walls 23A. The bottom wall 23 is formed by a c-plane. If the active surface 8 (first main surface 3) has the off angle inclined in the predetermined off direction at the predetermined angle with respect to the c-plane, the bottom wall 23 may have the off direction and the off angle like the active surface 8 (first main surface 3).

The second trench structure 20 includes a second trench 25, a second insulating film 26, and a second embedded electrode 27. The second trench 25 may be referred to as a “source trench,” the second insulating film 26 may be referred to as a “source insulating film,” and the second embedded electrode 27 may be referred to as a “source embedded electrode.” The second trench 25 is formed in the active surface 8 and demarcates a wall surface (the inner side wall 21, the outer side wall 22, and the bottom wall 23) of the second trench structure 20.

The second insulating film 26 covers a wall surface of the second trench 25 as a film. The second insulating film 26 may include at least one among a silicon oxide film, a silicon nitride film, and a silicon oxynitride film. In this embodiment, the second insulating film 26 has a single layer structure consisting of the silicon oxide film. The second insulating film 26 particularly preferably includes the silicon oxide film that consists of the oxide of the chip 2. The second embedded electrode 27 is embedded in the second trench 25 with the second insulating film 26 interposed therebetween. The second embedded electrode 27 may contain a conductive polysilicon.

The SiC semiconductor device 1A includes a third trench structure 30 that is formed in the active surface 8 at intervals from the plurality of second trench structures 20. A gate potential is to be applied to the third trench structure 30. The third trench structure 30 may be referred to as a “trench gate structure.” The third trench structure 30 penetrates through the body region 12 and reaches the first semiconductor region 6.

The third trench structure 30 is formed at an interval to the active surface 8 side from the bottom portion of the first semiconductor region 6 and opposes the second semiconductor region 7 with a portion of the first semiconductor region 6 interposed therebetween. The third trench structure 30 preferably has a depth substantially equal to the depth of the first trench structure 15 (second trench structure 20). The third trench structure 30 preferably has a depth substantially equal to the depth of the outer surface 9. The third trench structure 30 is preferably formed to be narrower in width than the first trench structure 15. A width of the third trench structure 30 is preferably substantially equal to a width of the second trench structure 20.

The third trench structure 30 is formed in a lattice pattern extending in the a-axis direction and the m-axis direction in regions between the plurality of second trench structures 20 such as to surround the plurality of second trench structures 20 in plan view. In other words, the third trench structure 30 is formed in annular shapes (specifically, quadrangle annular shapes) surrounding the respective second trench structures 20 in plan view. The third trench structure 30 demarcates, with the outer side walls 22 of the plurality of second trench structures 20, a plurality of second mesa portions 31 that extend in annular shapes (specifically, quadrangle annular shapes). The third trench structure 30 is electrically and mechanically connected to the first trench structure 15 in the peripheral edge portion of the active surface 8.

Specifically, the third trench structure 30 includes a plurality of third trench structures 30A extending in the a-axis direction and a plurality of third trench structures 30B extending in the m-axis direction. The plurality of third trench structures 30A are formed at intervals in the m-axis direction from the plurality of first outer side walls 22A such as to oppose the plurality of first outer side walls 22A in the m-axis direction and extend in band shapes in the a-axis direction in regions between the plurality of first outer side walls 22A. The plurality of third trench structures 30A are electrically and mechanically connected to the first trench structure 15 in the peripheral edge portion of the active surface 8.

Each third trench structure 30A has a pair of first gate side walls 32 extending in the a-axis direction and a first gate bottom wall 33 extending in the a-axis direction. The pair of first gate side walls 32 are formed by m-planes and the first gate bottom wall 33 is formed by a c-plane. If the active surface 8 (first main surface 3) has the off angle inclined in the predetermined off direction at the predetermined angle with respect to the c-plane, the first gate bottom wall 33 may have the off direction and the off angle like the active surface 8 (first main surface 3).

The plurality of third trench structures 30B are formed at intervals in the a-axis direction from the plurality of second outer side walls 22B such as to oppose the plurality of second outer side walls 22B in the a-axis direction and extend in band shapes in the m-axis direction in regions between the plurality of second outer side walls 22B. The plurality of third trench structures 30B intersect (specifically, are orthogonal to) the plurality of third trench structures 30A in the inner portion of the active surface 8 and, together with the plurality of third trench structures 30A, form a plurality of trench intersections 34.

In this embodiment, the plurality of trench intersections 34 each form a crossroad in plan view. If the plurality of second trench structures 20 are arrayed in the staggered manner in plan view, the plurality of trench intersections 34 each form a T-junction in plan view. The plurality of third trench structures 30B are electrically and mechanically connected to the first trench structure 15 in the peripheral edge portion of the active surface 8.

Each third trench structure 30B has a pair of second gate side walls 35 extending in the m-axis direction and a second gate bottom wall 36 extending in the m-axis direction. The pair of second gate side walls 35 are formed by a-planes and the second gate bottom wall 36 is formed by a c-plane. If the active surface 8 (first main surface 3) has the off angle inclined in the predetermined off direction at the predetermined angle with respect to the c-plane, the second gate bottom wall 36 may have the off direction and the off angle like the active surface 8 (first main surface 3). The trench intersections 34 are formed by intersections of the first gate bottom walls 33 and the second gate bottom walls 36.

The third trench structure 30 includes a third trench 37, a third insulating film 38, and a third embedded electrode 39. The third trench 37 may be referred to as a “gate trench,” the third insulating film 38 may be referred to as a “gate insulating film,” and the third embedded electrode 39 may be referred to as a “gate embedded electrode.” The third trench 37 is formed in the active surface 8 and demarcates a wall surface of the third trench structure 30. The third trench 37 is in communication with the first trench 16 in the peripheral edge portion of the active surface 8.

The third insulating film 38 covers a wall surface of the third trench 37 as a film. The third insulating film 38 is connected to the first insulating film 17 in communication portions of the first trench 16 and the third trench 37. The third insulating film 38 may include at least one among a silicon oxide film, a silicon nitride film, and a silicon oxynitride film. In this embodiment, the third insulating film 38 has a single layer structure consisting of the silicon oxide film. The third insulating film 38 particularly preferably includes the silicon oxide film that consists of the oxide of the chip 2.

The third embedded electrode 39 is embedded in the third trench 37 with the third insulating film 38 interposed therebetween. The third embedded electrode 39 is electrically and mechanically connected to the first embedded electrode 18 in communication portions of the first trench 16 and the third trench 37. The third embedded electrode 39 may contain a conductive polysilicon.

The SiC semiconductor device 1A includes a plurality of source regions 40 of the n-type that are formed in regions of a surface layer portion of the body region 12 along the third trench structure 30. Specifically, the plurality of source regions 40 are formed in the surface layer portion of the body region 12 in the plurality of second mesa portions 31. Each source region 40 has a higher n-type impurity concentration than the first semiconductor region 6. The n-type impurity concentration (maximum value) of the source region 40 may be not less than 1.0×10¹⁸ cm⁻³ and not more than 1.0×10²¹ cm⁻³. The plurality of source regions 40 are each formed at an interval to the active surface 8 side from a bottom portion of the body region 12 and formed in a layered shape extending along the active surface 8.

In this embodiment, each source region 40 is formed in an annular shape (specifically, a quadrangle annular shape) extending along the second mesa portion 31 such as to surround the corresponding second trench structure 20 in plan view and is connected to the second trench structure 20 and the third trench structure 30. Each source region 40 is exposed from the first outer side walls 22A and the second outer side walls 22B of the second trench structure 20 and is exposed from the first gate side walls 32 and the second gate side walls 35 of the third trench structure 30. Each source region 40, together with the first semiconductor region 6, forms a channel inside the body region 12.

With reference to FIG. 8 to FIG. 15, the SiC semiconductor device 1A includes a plurality of well regions 41 of the p-type that are each formed in a region inside the chip 2 along the corresponding second trench structure 20. In this embodiment, the plurality of well regions 41 have a higher p-type impurity concentration than the body region 12. As a matter of course, the plurality of well regions 41 may have a lower p-type impurity concentration than the body region 12 instead. The p-type impurity concentration (maximum value) of the well regions 41 may be not less than 1.0×10¹⁶ cm⁻³ and not more than 1.0×10¹⁹ cm⁻³.

Hereinafter, the arrangement of the single well region 41 shall be described specifically. In this embodiment, the well region 41 includes a well bottom wall portion 42, a first well side wall portion 43, and a second well side wall portion 44. The well bottom wall portion 42 may be referred to as a “first well portion,” the first well side wall portion 43 may be referred to as a “second well portion,” and the second well side wall portion 44 may be referred to as a “third well portion.”

The well bottom wall portion 42 is formed in a region along the bottom wall 23 of the second trench structure 20. Specifically, the well bottom wall portion 42 is formed in a region along the pair of first bottom walls 23A and the pair of second bottom walls 23B. The well bottom wall portion 42 is formed in an annular shape (specifically, a quadrangle annular shape) extending along the bottom wall 23 of the second trench structure 20 in plan view and covers a whole region of the bottom wall 23 of the second trench structure 20. The well bottom wall portion 42 is formed at an interval to the active surface 8 side from the bottom portion of the first semiconductor region 6 and opposes the second semiconductor region 7 with a portion of the first semiconductor region 6 interposed therebetween.

The first well side wall portion 43 is drawn out to the inner side wall 21 side of the second trench structure 20 from the well bottom wall portion 42 and is formed in a region along the inner side wall 21. Specifically, the first well side wall portion 43 is formed in a region inside the first mesa portion 24 along the pair of first inner side walls 21A and the pair of second inner side walls 21B.

The first well side wall portion 43 is formed in an annular shape (specifically, a quadrangle annular shape) extending along the inner side wall 21 such as to surround an inner portion of the body region 12 in plan view. The first well side wall portion 43 is connected to the body region 12 in a surface layer portion of the first mesa portion 24. A thickness of the first well side wall portion 43 on a basis of the inner side wall 21 is less than a thickness of the well bottom wall portion 42 on a basis of the bottom wall 23.

The second well side wall portion 44 is drawn out to the outer side wall 22 side of the second trench structure 20 from the bottom wall 23 side of the second trench structure 20 and is formed in a region along the outer side wall 22. Specifically, the second well side wall portion 44 is formed in a region in the second mesa portion 31 along the pair of first outer side walls 22A and the pair of second outer side walls 22B.

The second well side wall portion 44 is formed in the second mesa portion 31 in an annular shape (specifically, a quadrangle annular shape) surrounding the second trench structure 20 at an interval from the third trench structure 30. The second well side wall portion 44 is connected to the body region 12 in a surface layer portion of the second mesa portion 31. A thickness of the second well side wall portion 44 on a basis of the outer side wall 22 is less than the thickness of the well bottom wall portion 42 on the basis of the bottom wall 23.

With reference to FIG. 8 to FIG. 15, the SiC semiconductor device 1A includes a plurality of contact regions 50 of the p-type that are each formed in a region inside the chip 2 along the corresponding second trench structure 20. Specifically, the plurality of contact regions 50 are each formed in a region inside the corresponding well region 41 along the corresponding second trench structure 20.

The plurality of contact regions 50 have a higher p-type impurity concentration than the body region 12. The plurality of contact regions 50 have a higher p-type impurity concentration than the well regions 41. The p-type impurity concentration (maximum value) of the contact regions 50 may be not less than 1.0×10¹⁷ cm⁻³ and not more than 1.0×10²¹ cm⁻³. The contact regions 50 preferably contain aluminum (Al) as the p-type impurity.

Hereinafter, the arrangement of the single contact region 50 shall be described specifically. The contact region 50 includes at least one (in this embodiment, a plurality of a) first region 51 formed in the surface layer portion of the active surface 8 in the second mesa portion 31. Specifically, the plurality of first regions 51 are formed in the surface layer portion of the body region 12 in the second mesa portion 31. The plurality of first regions 51 are each formed in a region along the outer side wall 22 of the second trench structure 20. In this embodiment, the plurality of first regions 51 are formed at intervals along a circumferential direction of the outer side wall 22.

Specifically, the plurality of first regions 51 include a pair of first regions 51A that are formed in regions along the pair of first outer side walls 22A and a pair of first regions 51B that are formed in regions along the pair of second outer side walls 22B. The pair of first regions 51A are preferably formed to be narrower than the first outer side walls 22A in the a-axis direction. In this embodiment, the pair of first regions 51A are formed to be narrower than the first inner side walls 21A in the a-axis direction.

The pair of first regions 51A are formed in the regions along the pair of first outer side walls 22A at intervals in the a-axis direction from the pair of second outer side walls 22B. The pair of first regions 51A preferably oppose each other in the m-axis direction. The pair of first regions 51A are preferably formed in regions along central portions of the pair of first outer side walls 22A. As a matter of course, the pair of first regions 51A may be shifted with respect to each other in the a-axis direction such as not to be opposed in the m-axis direction.

A width in the a-axis direction of each first region 51A is preferably not more than ½ of a width in the a-axis direction of the first outer side walls 22A. The width in the a-axis direction of each first region 51A is particularly preferably not more than ¼ of the width in the a-axis direction of the first outer side walls 22A. The width in the a-axis direction of each first region 51A may be not less than 1/10 of the width in the a-axis direction of the first outer side walls 22A.

The pair of first regions 51B are preferably formed to be narrower than the second outer side walls 22B in the m-axis direction. In this embodiment, the pair of first regions 51B are formed to be narrower than the second inner side walls 21B in the m-axis direction. The pair of first regions 51B are formed in the regions along the pair of second outer side walls 22B at intervals in the m-axis direction from the pair of first outer side walls 22A.

The pair of first regions 51B preferably oppose each other in the a-axis direction. The pair of first regions 51B are preferably formed in regions along central portions of the second outer side walls 22B. As a matter of course, the pair of first regions 51B may be shifted with respect to each other in the m-axis direction such as not to be opposed in the a-axis direction.

A width in the m-axis direction of each first region 51B is preferably not more than ½ of a width in the m-axis direction of the second outer side walls 22B. The width in the m-axis direction of each first region 51B is particularly preferably not more than ¼ of the width in the m-axis direction of the second outer side walls 22B. The width in the m-axis direction of each first region 51B may be not less than 1/10 of the width in the m-axis direction of the second outer side walls 22B.

With reference to FIG. 16A and FIG. 16B, each first region 51 is formed at an interval to the active surface 8 side from a bottom portion of the body region 12 and opposes the first semiconductor region 6 with a portion of the body region 12 interposed therebetween. That is, the first region 51 has a bottom portion positioned inside the body region 12. The first region 51 is formed at an interval to the second trench structure 20 side from the third trench structure 30 and is connected to the source region 40.

The first region 51 has a concentration gradient with which a p-type impurity concentration decreases from the active surface 8 side toward the bottom portion side. In other words, the first region 51 includes a first high concentration region 51H at the active surface 8 side and a first low concentration region 51L at the bottom portion side and has the concentration gradient with which the p-type impurity concentration decreases from the first high concentration region 51H toward the first low concentration region 51L.

If an intermediate value between a maximum value of the p-type impurity concentration and a minimum value of the p-type impurity concentration is set in the first region 51, the first high concentration region 51H is a region between the maximum value of the p-type impurity concentration and the intermediate value of the p-type impurity concentration. On the other hand, the first low concentration region 51L is a region between the intermediate value of the p-type impurity concentration and the minimum value of the p-type impurity concentration.

A maximum value and a minimum value of the p-type impurity concentration of the first high concentration region 51H are higher than the maximum value of the p-type impurity concentration of the body region 12. The maximum value of the p-type impurity concentration of the first high concentration region 51H may be not less than 1.0×10¹⁹ cm⁻³ and not more than 1.0×10²¹ cm⁻³. The first high concentration region 51H extends in a layered shape along the active surface 8 and is connected to the second trench structure 20 and the source region 40.

A maximum value and a minimum value of the p-type impurity concentration of the first low concentration region 51L are not more than the minimum value of the first high concentration region 51H but higher than the maximum value of the p-type impurity concentration of the body region 12. The minimum value of the p-type impurity concentration of the first low concentration region 51L is preferably not less than 1/1000 and not more than ½ of the maximum value of the p-type impurity concentration of the first high concentration region 51H. The minimum value of the p-type impurity concentration of the first low concentration region 51L may be not less than 1.0×10¹⁷ cm⁻³ and not more than 1.0×10²⁰ cm⁻³. The first low concentration region 51L extends in a layered shape along the first high concentration region 51H (active surface 8) and is connected to the second trench structure 20 and the source region 40.

The first low concentration region 51L may have a thickness of not less than a thickness of the first high concentration region 51H or may have a thickness less than the thickness of the first high concentration region 51H. That is, with respect to a thickness direction intermediate portion of the first region 51, a boundary portion between the first high concentration region 51H and the first low concentration region 51L may be positioned at the active surface 8 side or may be positioned at the bottom portion side of the first region 51. In consideration of a contact resistance, it is preferable to form the first high concentration region 51H thickly. That is, the first low concentration region 51L preferably has a thickness less than the thickness of the first high concentration region 51H.

The contact region 50 includes at least one (in this embodiment, a plurality of a) second region 52 formed in a region inside the chip 2 along the bottom wall 23 of the second trench structure 20. Specifically, the plurality of second regions 52 are each formed in a region inside the well region 41 along the bottom wall 23 of the second trench structure 20 at an interval from the bottom portion of the body region 12. That is, the plurality of second regions 52 are formed inside the well bottom wall portion 42.

In this embodiment, the plurality of second regions 52 are formed at intervals along a circumferential direction of the bottom wall 23. Specifically, the plurality of second regions 52 include a pair of second regions 52A that are formed in regions along the pair of first bottom walls 23A and a pair of second regions 52B that are formed in regions along the pair of second bottom walls 23B.

The pair of second regions 52A are preferably formed to be narrower than the first outer side walls 22A in the a-axis direction. In this embodiment, the pair of second regions 52A are formed to be narrower than the first inner side walls 21A in the a-axis direction. The pair of second regions 52A are formed in the regions along the pair of first bottom walls 23A at intervals in the a-axis direction from the pair of second bottom walls 23B. The pair of second regions 52A preferably oppose each other in the m-axis direction.

The pair of second regions 52A are preferably formed in regions along central portions of the pair of first bottom walls 23A. In this embodiment, the pair of second regions 52A oppose the pair of first regions 51A in the m-axis direction. As a matter of course, the pair of second regions 52A may be shifted with respect to each other in the a-axis direction such as not to be opposed in the m-axis direction. In this case, one second region 52A preferably opposes the adjacent one first region 51A in the m-axis direction and the other second region 52B preferably opposes the adjacent other first region 51A in the m-axis direction.

A width in the a-axis direction of each second region 52A is preferably not more than ½ of a width in the a-axis direction of the first bottom walls 23A. The width in the a-axis direction of each second region 52A is particularly preferably not more than ¼ of the width in the a-axis direction of the first bottom walls 23A. The width in the a-axis direction of each second region 52A may be not less than 1/10 of the width in the a-axis direction of the first bottom walls 23A. The width in the a-axis direction of each second region 52A is preferably substantially equal to the width in the a-axis direction of each first region 51A.

The pair of second regions 52B are preferably formed to be narrower than the second outer side walls 22B in the m-axis direction. In this embodiment, the pair of second regions 52B are formed to be narrower than the second inner side walls 21B in the m-axis direction. The pair of second regions 52B are formed in the regions along the pair of second bottom walls 23B at intervals in the m-axis direction from the pair of first bottom walls 23A. The pair of second regions 52B preferably oppose each other in the a-axis direction.

The pair of second regions 52B are preferably formed in regions along central portions of the second bottom walls 23B. In this embodiment, the pair of second regions 52B oppose the pair of first regions 51B in the a-axis direction. As a matter of course, the pair of second regions 52B may be shifted with respect to each other in the m-axis direction such as not to be opposed in the a-axis direction. In this case, one second region 52B preferably opposes the neighboring one first region 51B in the a-axis direction and the other second region 52B preferably opposes the neighboring other first region 51B in the a-axis direction.

A width in the m-axis direction of each second region 52B is preferably not more than ½ of a width in the m-axis direction of the second bottom walls 23B. The width in the m-axis direction of each second region 52B is particularly preferably not more than ¼ of the width in the m-axis direction of the second bottom walls 23B. The width in the m-axis direction of each second region 52B may be not less than 1/10 of the width in the m-axis direction of the second bottom walls 23B. The width in the m-axis direction of each second region 52B is preferably substantially equal to the width in the m-axis direction of each first region 51B.

With reference to FIG. 16A and FIG. 16B, each second region 52 is formed at an interval to the bottom wall 23 side of the second trench structure 20 from a bottom portion of the well region 41 and opposes the first semiconductor region 6 with a portion of the well region 41 interposed therebetween. That is, the second region 52 has a bottom portion positioned inside the well region 41. The second region 52 extends in a layered shape along the bottom wall 23 and is connected to the bottom wall 23 of the second trench structure 20.

Unlike the first region 51, the second region 52 does not include the first high concentration region 51H and the first low concentration region 51L. A maximum value of the p-type impurity concentration of the second region 52 is lower than the maximum value of the p-type impurity concentration of the first region 51. The second region 52 may have a p-type impurity concentration that is substantially fixed in the thickness direction. The second region 52 may have a concentration gradient with which the p-type impurity concentration decreases from the bottom wall 23 toward the well region 41. In this case, a decrease ratio of the p-type impurity concentration of the second region 52 is less than a decrease ratio of the p-type impurity concentration of the first region 51.

The maximum value of the p-type impurity concentration of the second region 52 is lower than the maximum value of the p-type impurity concentration of the first high concentration region 51H and higher than the maximum value of the p-type impurity concentration of the well region 41. The maximum value of the p-type impurity concentration of the second region 52 is preferably not more than the intermediate value of the p-type impurity concentration of the first region 51. A minimum value of the p-type impurity concentration of the second region 52 is preferably substantially equal to the minimum value of the p-type impurity concentration of the first low concentration region 51L.

The maximum value of the p-type impurity concentration of the second region 52 is preferably not less than 1/1000 and not more than ½ of the maximum value of the p-type impurity concentration of the first high concentration region 51H. The maximum value of the p-type impurity concentration of the second region 52 may be not less than 1.0×10¹⁷ cm⁻³ and not more than 1.0×10²⁰ cm⁻³. If the p-type impurity concentration of the first low concentration region 51L is increased in accompaniment with introduction of the first high concentration region 51H, the maximum value of the p-type impurity concentration of the second region 52 is at times less than the maximum value of the p-type impurity concentration of the first low concentration region 51L.

The second region 52 has a thickness greater than the thickness of the first high concentration region 51H. Also, the second region 52 has a thickness greater than the thickness of the first low concentration region 51L. The thickness of the second region 52 may be not more than a thickness of the first region 51 or may be greater than the thickness of the first region 51. The thickness of the second region 52 is preferably substantially equal to the thickness of the first region 51.

The contact region 50 includes at least one (in this embodiment, one) third region 53 formed in the surface layer portion of the active surface 8 in the first mesa portion 24. Specifically, the third region 53 is formed in a surface layer portion of the body region 12 in the first mesa portion 24. In this embodiment, the third region 53 is formed in a whole region of the surface layer portion of the body region 12 in the first mesa portion 24 and is connected to the inner side wall 21 of the second trench structure 20.

Specifically, the third region 53 is connected to the pair of first inner side walls 21A and the pair of second inner side walls 21B. The third region 53 is formed at an interval to the active surface 8 side from the bottom portion of the body region 12 and opposes the first semiconductor region 6 with a portion of the body region 12 interposed therebetween. That is, the third region 53 has a bottom portion positioned inside the body region 12.

The third region 53 has a concentration gradient with which a p-type impurity concentration decreases from the active surface 8 side toward the bottom portion side. In other words, the third region 53 includes a second high concentration region 53H at the active surface 8 side and a second low concentration region 53L at the bottom portion side and has the concentration gradient with which the p-type impurity concentration decreases from the second high concentration region 53H toward the second low concentration region 53L.

If an intermediate value between a maximum value of the p-type impurity concentration and a minimum value of the p-type impurity concentration is set in the third region 53, the second high concentration region 53H is a region between the maximum value of the p-type impurity concentration and the intermediate value of the p-type impurity concentration. On the other hand, the second low concentration region 53L is a region between the intermediate value of the p-type impurity concentration and the minimum value of the p-type impurity concentration.

A maximum value and a minimum value of the second high concentration region 53H are higher than the maximum value of the p-type impurity concentration of the body region 12. The maximum value of the p-type impurity concentration of the second high concentration region 53H may be not less than 1.0×10¹⁹ cm⁻³ and not more than 1.0×10²¹ cm⁻³. In this embodiment, the p-type impurity concentration of the second high concentration region 53H is substantially equal to the p-type impurity concentration of the first high concentration region 51H of the first region 51. The second high concentration region 53H extends in a layered shape along the active surface 8 and is connected to the inner side wall 21 (the first inner side walls 21A and the second inner side walls 21B) of the second trench structure 20.

A maximum value and a minimum value of the p-type impurity concentration of the second low concentration region 53L are not more than the minimum value of the second high concentration region 53H but higher than the maximum value of the p-type impurity concentration of the body region 12. The minimum value of the p-type impurity concentration of the second low concentration region 53L is preferably not less than 1/1000 and not more than ½ of the maximum value of the p-type impurity concentration of the second high concentration region 53H. The minimum value of the p-type impurity concentration of the second low concentration region 53L may be not less than 1.0×10¹⁷ cm⁻³ and not more than 1.0×10²⁰ cm⁻³.

In this embodiment, the p-type impurity concentration of the second low concentration region 53L is substantially equal to the p-type impurity concentration of the first low concentration region 51L of the first region 51. The second low concentration region 53L extends in a layered shape along the second high concentration region 53H (active surface 8) and is connected to the inner side wall 21 (the first inner side walls 21A and the second inner side walls 21B) of the second trench structure 20.

The second low concentration region 53L may have a thickness of not less than a thickness of the second high concentration region 53H or may have a thickness less than the thickness of the second high concentration region 53H. That is, with respect to a thickness direction intermediate portion of the third region 53, a boundary portion between the second high concentration region 53H and the second low concentration region 53L may be positioned at the active surface 8 side or may be positioned at the bottom portion side of the third region 53.

In consideration of the contact resistance, it is preferable to form the second high concentration region 53H thickly. That is, the second low concentration region 53L preferably has a thickness less than the thickness of the second high concentration region 53H. In this embodiment, the second high concentration region 53H has a thickness substantially equal to the thickness of the first high concentration region 51H and the first high concentration region 51H has a thickness substantially equal to the thickness of the second high concentration region 53H.

A relationship of the p-type impurity concentration established between the second high concentration region 53H and the second region 52 is substantially the same as the relationship of the p-type impurity concentration established between the first high concentration region 51H and the second region 52. Also, a relationship of the p-type impurity concentration established between the second low concentration region 53L and the second region 52 is substantially the same as the relationship of the p-type impurity concentration established between the first low concentration region 51L and the second region 52.

The contact region 50 includes at least one (in this embodiment, a plurality of a) first connection region 54 formed in a region inside the chip 2 along the outer side wall 22 of the second trench structure 20. Specifically, the plurality of first connection regions 54 are each formed in a region inside the well region 41 along the outer side wall 22 of the second trench structure 20 such as to each connect the first region 51 and the second region 52 that are adjacent thereto in an up/down direction. That is, the plurality of first connection regions 54 are formed inside the second well side wall portion 44.

Specifically, the plurality of first connection regions 54 include a pair of first connection regions 54A that are formed in regions inside the chip 2 along the pair of first outer side walls 22A and a pair of first connection regions 54B that are formed in regions inside the chip 2 along the pair of second outer side walls 22B. The pair of first connection regions 54A are each formed in the region along the corresponding first outer side wall 22A such as to connect the first region 51A and the second region 52A that are adjacent thereto in the up/down direction.

The pair of first connection regions 54A are preferably formed to be narrower than the first outer side walls 22A in the a-axis direction. In this embodiment, the pair of first connection regions 54A are formed to be narrower than the first inner side walls 21A in the a-axis direction. The pair of first connection regions 54A are formed in the regions along the first outer side walls 22A at intervals in the a-axis direction from the pair of second outer side walls 22B. The pair of first connection regions 54A are preferably formed in regions along the central portions of the pair of first outer side walls 22A. Formation locations of the pair of first connection regions 54A are adjusted in accordance with formation locations of the corresponding first regions 51A and second regions 52A.

A width in the a-axis direction of each first connection region 54A is preferably not more than ½ of the width in the a-axis direction of the first outer side walls 22A. The width in the a-axis direction of each first connection region 54A is particularly preferably not more than ¼ of the width in the a-axis direction of the first outer side walls 22A. The width in the a-axis direction of each first connection region 54A may be not less than 1/10 of the width in the a-axis direction of the first outer side walls 22A. The width in the a-axis direction of each first connection region 54A is preferably substantially equal to the width in the a-axis direction of each first region 51A and the width in the a-axis direction of each second region 52A.

The pair of first connection regions 54B are each formed in the region along the corresponding second outer side wall 22B such as to connect the first region 51B and the second region 52B that are adjacent thereto in the up/down direction. The pair of first connection regions 54B are preferably formed to be narrower than the second outer side walls 22B in the m-axis direction. In this embodiment, the pair of first connection regions 54B are formed to be narrower than the second inner side walls 21B in the m-axis direction.

The pair of first connection regions 54B are formed in the regions along the pair of second outer side walls 22B at intervals in the m-axis direction from the pair of first outer side walls 22A. The pair of first connection regions 54B are preferably formed in regions along the central portions of the pair of second outer side walls 22B. Formation locations of the pair of first connection regions 54B are adjusted in accordance with the formation locations of the corresponding first regions 51B and second regions 52B.

A width in the m-axis direction of each first connection region 54B is preferably not more than ½ of the width in the m-axis direction of the second outer side walls 22B. The width in the m-axis direction of each first connection region 54B is particularly preferably not more than ¼ of the width in the m-axis direction of the second outer side walls 22B. The width in the m-axis direction of each first connection region 54B may be not less than 1/10 of the width in the m-axis direction of the second outer side walls 22B. The width in the m-axis direction of each first connection region 54B is preferably substantially equal to the width in the m-axis direction of each first region 51B and the width in the m-axis direction of each second region 52B.

With reference to FIG. 16A and FIG. 16B, each first connection region 54 is formed in a layered shape extending in the c-axis direction along the outer side wall 22 of the second trench structure 20 such as to be drawn out from inside the well region 41 (second well side wall portion 44) into the body region 12. The first connection region 54 is connected to the first region 51 at the surface layer portion side of the active surface 8 and connected to the second region 52 at the bottom wall 23 side of the second trench structure 20. Specifically, the first connection region 54 is connected to the first low concentration region 51L of the first region 51. The first connection region 54 opposes the first semiconductor region 6 with a portion of the well region 41 (second well side wall portion 44) interposed therebetween in a horizontal direction.

Unlike the first region 51, the first connection region 54 does not include the first high concentration region 51H and the first low concentration region 51L. A maximum value of the p-type impurity concentration of the first connection region 54 is lower than the maximum value of the p-type impurity concentration of the first region 51. The first connection region 54 may have a p-type impurity concentration that is substantially fixed in the horizontal direction. The first connection region 54 may have a concentration gradient with which the p-type impurity concentration decreases in the horizontal direction from the outer side wall 22 of the second trench structure 20. In this case, a decrease ratio of the p-type impurity concentration of the first connection region 54 is less than the decrease ratio of the p-type impurity concentration of the first region 51.

The maximum value and a minimum value of the p-type impurity concentration of the first connection region 54 are lower than the maximum value of the p-type impurity concentration of the first high concentration region 51H and higher than the maximum value of the p-type impurity concentration of the well region 41. The maximum value of the p-type impurity concentration of the first connection region 54 is preferably not more than the intermediate value of the p-type impurity concentration of the first region 51. The minimum value of the p-type impurity concentration of the first connection region 54 is preferably substantially equal to the minimum value of the p-type impurity concentration of the first low concentration region 51L.

The maximum value of the p-type impurity concentration of the first connection region 54 is preferably not less than 1/1000and not more than ½ of the maximum value of the p-type impurity concentration of the first high concentration region 51H. The maximum value of the p-type impurity concentration of the first connection region 54 may be not less than 1.0×10¹⁷ cm⁻³ and not more than 1.0×10²⁰ cm⁻³. If the p-type impurity concentration of the first low concentration region 51L is increased in accompaniment with the introduction of the first high concentration region 51H, the maximum value of the p-type impurity concentration of the first connection region 54 is at times less than the maximum value of the p-type impurity concentration of the first low concentration region 51L.

A thickness of the first connection region 54 on a basis of the outer side wall 22 is less than the thickness of the first region 51 on a basis of the active surface 8. The thickness of the first connection region 54 on the basis of the outer side wall 22 is less than the thickness of the second region 52 on a basis of the bottom wall 23 of the second trench structure 20. The thickness of the first connection region 54 may be not more than the thickness of the first high concentration region 51H or may exceed the thickness of the first high concentration region 51H.

The thickness of the first connection region 54 may be not more than the thickness of the first low concentration region 51L or may exceed the thickness of the first low concentration region 51L. p-type impurity concentration and thickness relationships between the first connection region 54 and the third region 53 are the same as the p-type impurity concentration and thickness relationships between the first connection region 54 and the first region 51 and description thereof shall thus be omitted.

The contact region 50 includes at least one (in this embodiment, a plurality of a) second connection region 55 formed in a region inside the chip 2 along the inner side wall 21 of the second trench structure 20. Specifically, the plurality of second connection regions 55 are respectively formed in regions inside the well region 41 along the inner side wall 21 of the second trench structure 20 such as to respectively connect the plurality of second regions 52 and the third region 53. That is, the plurality of second connection regions 55 are formed inside the first well side wall portion 43.

Specifically, the plurality of second connection regions 55 include a pair of second connection regions 55A that are formed in regions inside the chip 2 along the pair of first inner side walls 21A and a pair of second connection regions 55B that are formed in regions inside the chip 2 along the pair of second inner side walls 21B. The pair of second connection regions 55A are formed in regions along the corresponding first inner side walls 21A such as to connect the pair of second regions 52A and the third region 53.

The pair of second connection regions 55A are preferably formed to be narrower than the first inner side walls 21A in the a-axis direction. The pair of second connection regions 55A are formed in the regions along the first inner side walls 21A at intervals in the a-axis direction from the pair of second inner side walls 21B. The pair of second connection regions 55A are preferably formed in regions along the central portions of the pair of first inner side walls 21A. Formation locations of the pair of second connection regions 55A are adjusted in accordance with the formation locations of the corresponding second regions 52A.

A width in the a-axis direction of each second connection region 55A is preferably not more than ½ of the width in the a-axis direction of the first inner side walls 21A. The width in the a-axis direction of each second connection region 55A is particularly preferably not more than ⅓ of the width in the a-axis direction of the first inner side walls 21A. The width in the a-axis direction of each second connection region 55A may be not less than 1/10 of the width in the a-axis direction of the first inner side walls 21A. The width in the a-axis direction of each second connection region 55A is preferably substantially equal to the width in the a-axis direction of each second region 52A.

The pair of second connection regions 55B are formed in the regions along the corresponding second inner side walls 21B such as to connect the pair of second regions 52B and the third region 53. The pair of second connection regions 55B are preferably formed to be narrower than the second inner side walls 21B in the m-axis direction. The pair of second connection regions 55B are formed in the regions along the pair of second inner side walls 21B at intervals in the m-axis direction from the pair of first inner side walls 21A. The pair of second connection regions 55B are preferably formed in regions along the central portions of the pair of second inner side walls 21B. Formation locations of the pair of second connection regions 55B are adjusted in accordance with the formation locations of the corresponding second regions 52B.

A width in the m-axis direction of each second connection region 55B is preferably not more than ½ of the width in the m-axis direction of the second inner side walls 21B. The width in the m-axis direction of each second connection region 55B is particularly preferably not more than ⅓ of the width in the m-axis direction of the second inner side walls 21B. The width in the m-axis direction of each second connection region 55B may be not less than 1/10 of the width in the m-axis direction of the second inner side walls 21B. The width in the m-axis direction of each second connection region 55B is preferably substantially equal to the width in the m-axis direction of each second region 52B.

With reference to FIG. 16A and FIG. 16B, each second connection region 55 is formed in a layered shape extending in the c-axis direction along the inner side wall 21 of the second trench structure 20 such as to be drawn out from inside the well region 41 (first well side wall portion 43) into the body region 12. The second connection region 55 is connected to the second region 52 at the bottom wall 23 side of the second trench structure 20 and connected to the third region 53 at the surface layer portion side of the active surface 8. Specifically, the second connection region 55 is connected to the second low concentration region 53L of the third region 53. The second connection region 55 opposes the first semiconductor region 6 with a portion of the well region 41 (first well side wall portion 43) interposed therebetween in the horizontal direction.

Unlike the first region 51, the second connection region 55 does not include the first high concentration region 51H and the first low concentration region 51L. A maximum value of the p-type impurity concentration of the second connection region 55 is lower than the maximum value of the p-type impurity concentration of the first region 51. The second connection region 55 may have a p-type impurity concentration that is substantially fixed in the horizontal direction. The second connection region 55 may have a concentration gradient with which the p-type impurity concentration decreases in the horizontal direction from the inner side wall 21 of the second trench structure 20. In this case, a decrease ratio of the p-type impurity concentration of the second connection region 55 is less than the decrease ratio of the p-type impurity concentration of the first region 51.

The maximum value and a minimum value of the p-type impurity concentration of the second connection region 55 are lower than the maximum value of the p-type impurity concentration of the first high concentration region 51H and higher than the maximum value of the p-type impurity concentration of the well region 41. The maximum value of the p-type impurity concentration of the second connection region 55 is preferably not more than the intermediate value of the p-type impurity concentration of the first region 51. The minimum value of the p-type impurity concentration of the second connection region 55 is preferably substantially equal to the minimum value of the p-type impurity concentration of the first low concentration region 51L.

The maximum value of the p-type impurity concentration of the second connection region 55 is preferably not less than 1/1000 and not more than ½ of the maximum value of the p-type impurity concentration of the first high concentration region 51H. The maximum value of the p-type impurity concentration of the second connection region 55 may be not less than 1.0×10¹⁷ cm⁻³ and not more than 1.0×10²⁰ cm⁻³. If the p-type impurity concentration of the first low concentration region 51L is increased in accompaniment with the introduction of the first high concentration region 51H, the maximum value of the p-type impurity concentration of the second connection region 55 is at times less than the maximum value of the p-type impurity concentration of the first low concentration region 51L.

A thickness of the second connection region 55 on a basis of the inner side wall 21 is less than the thickness of the first region 51 on the basis of the active surface 8. The thickness of the second connection region 55 on the basis of the inner side wall 21 is less than the thickness of the second region 52 on the basis of the bottom wall 23 of the second trench structure 20. The thickness of the second connection region 55 may be not more than the thickness of the first high concentration region 51H or may exceed the thickness of the first high concentration region 51H.

The thickness of the second connection region 55 may be not more than the thickness of the first low concentration region 51L or may exceed the thickness of the first low concentration region 51L. p-type impurity concentration and thickness relationships between the second connection region 55 and the third region 53 are the same as the p-type impurity concentration and thickness relationships between the second connection region 55 and the first region 51 and description thereof shall thus be omitted.

With reference to FIG. 8 to FIG. 15, the SiC semiconductor device 1A includes a plurality of gate well regions 65 of the p-type that are formed in regions inside the chip 2 along the plurality of trench intersections 34. The plurality of gate well regions 65 have a lower p-type impurity concentration than the contact regions 50. In this embodiment, the plurality of gate well regions 65 have a higher p-type impurity concentration than the body region 12. As a matter of course, the plurality of gate well regions 65 may have a lower p-type impurity concentration than the body region 12.

The plurality of gate well regions 65 preferably have a p-type impurity concentration substantially equal to the well regions 41. The p-type impurity concentration (maximum value) of the gate well regions 65 may be not less than 1.0×10¹⁶ cm⁻³ and not more than 1.0×10¹⁹ cm⁻³. The plurality of gate well regions 65 are formed in the regions along the plurality of trench intersections 34 at intervals in the a-axis direction and the m-axis direction and expose regions of a bottom wall (the first gate bottom walls 33 and the second gate bottom walls 36) of the third trench structure 30 outside the plurality of trench intersections 34.

Each gate well region 65 covers the first gate side walls 32 of the third trench structure 30A and the second gate side walls 35 of the third trench structure 30B at corner portions of the corresponding second mesa portions 31 and is connected to the body region 12 in surface layer portions of the corresponding second mesa portions 31. The plurality of gate well regions 65 are formed at an interval to the active surface 8 side from the bottom portion of the first semiconductor region 6 and oppose the second semiconductor region 7 with portions of the first semiconductor region 6 interposed therebetween. Bottom portions of the plurality of gate well regions 65 are preferably formed at substantially the same depth position as the bottom portions of the well regions 41.

With reference to FIG. 6 and FIG. 7, the SiC semiconductor device 1A includes a wiring well region 66 that is formed in a region inside the chip 2 along the wall surface of the first trench structure 15. The wiring well region 66 has a lower p-type impurity concentration than the contact regions 50. In this embodiment, the wiring well region 66 has a higher p-type impurity concentration than the body region 12.

As a matter of course, the wiring well region 66 may have a lower p-type impurity concentration than the body region 12. The wiring well region 66 preferably has a p-type impurity concentration substantially equal to the well regions 41. The p-type impurity concentration (maximum value) of the wiring well region 66 may be not less than 1.0×10¹⁶ cm⁻³ and not more than 1.0×10¹⁹ cm⁻³.

The wiring well region 66 is formed in a region along an inner wall, an outer wall, and a bottom wall of the first trench structure 15 at the pad portion 15a and the line portion 15b of the first trench structure 15 and is connected to the body region 12 in the surface layer portion of the active surface 8. The wiring well region 66 is formed at an interval to the active surface 8 side from the bottom portion of the first semiconductor region 6 and opposes the second semiconductor region 7 with a portion of the first semiconductor region 6 interposed therebetween. A bottom portion of the wiring well region 66 is preferably formed at substantially the same depth position as the bottom portions of the well regions 41.

With reference to FIG. 17, the SiC semiconductor device 1A includes an outer well region 67 of the p-type that is formed in a surface layer portion of the outer surface 9. The outer well region 67 has a lower p-type impurity concentration than the contact regions 50. In this embodiment, the outer well region 67 has a higher p-type impurity concentration than the body region 12.

As a matter of course, the outer well region 67 may have a lower p-type impurity concentration than the body region 12. The outer well region 67 preferably has a p-type impurity concentration substantially equal to the well regions 41. The p-type impurity concentration (maximum value) of the outer well region 67 may be not less than 1.0×10¹⁶ cm⁻³ and not more than 1.0×10¹⁹ cm⁻³.

The outer well region 67 is formed at intervals to the active surface 8 side from the peripheral edge (first to fourth side surfaces 5A to 5D) of the outer surface 9 in plan view and extends in a band shape along the active surface 8. In this embodiment, the outer well region 67 is formed in an annular shape (specifically, a quadrangle annular shape) surrounding the active surface 8 in plan view. The outer well region 67 extends from the surface layer portion of the outer surface 9 toward surface layer portions of the first to fourth connecting surfaces 10A to 10D and covers the first to fourth connecting surfaces 10A to 10D. The outer well region 67 is electrically connected to the body region 12 in the surface layer portion of the active surface 8.

The outer well region 67 is formed at an interval to the outer surface 9 side from the bottom portion of the first semiconductor region 6 and opposes the second semiconductor region 7 with a portion of the first semiconductor region 6 interposed therebetween. The outer well region 67 is positioned further to the bottom portion side of the first semiconductor region 6 than the bottom walls 23 of the plurality of second trench structures 20. A bottom portion of the outer well region 67 is positioned further to the bottom portion side of the first semiconductor region 6 than bottom portions (bottom portions of the second region 52) of the contact regions 50. The bottom portion of the outer well region 67 is preferably formed at substantially the same depth position as the bottom portions of the well regions 41.

The SiC semiconductor device 1A includes an outer contact region 68 of the p-type that is formed in a surface layer portion of the outer well region 67. The outer contact region 68 is formed in the surface layer portion of the outer well region 67 at intervals from the peripheral edge (first to fourth connecting surfaces 10A to 10D) of the active surface 8 and the peripheral edge (first to fourth side surfaces 5A to 5D) of the outer surface 9 in plan view and is formed in a band shape extending along the active surface 8. In this embodiment, the outer contact region 68 is formed in an annular shape (specifically, a quadrangle annular shape) surrounding the active surface 8 in plan view.

The outer contact region 68 is formed at an interval to the outer surface 9 side from the bottom portion of the outer well region 67 and opposes the first semiconductor region 6 with a portion of the outer well region 67 interposed therebetween. The outer contact region 68 is positioned further to the bottom portion side of the first semiconductor region 6 than the bottom walls 23 of the plurality of second trench structures 20. A bottom portion of the outer contact region 68 is preferably formed at substantially the same depth position as the bottom portions (the bottom portions of the second region 52) of the contact regions 50.

The outer contact region 68 has a higher p-type impurity concentration than the body region 12. The outer contact region 68 has a higher p-type impurity concentration than the outer well region 67. The p-type impurity concentration (maximum value) of the outer contact region 68 may be not less than 1.0×10¹⁷ cm⁻³ and not more than 1.0×10²¹ cm⁻³. The outer contact region 68 preferably has a p-type impurity concentration substantially equal to the first regions 51 of the contact regions 50. The outer contact region 68 preferably contains aluminum (Al) as the p-type impurity.

That is, in this embodiment, the outer contact region 68 has a concentration gradient with which the p-type impurity concentration decreases from the outer side surface 9 side toward a bottom portion side. In other words, the outer contact region 68 includes a third high concentration region 68H at the outer side surface 9 side and a third low concentration region 68L at the bottom portion side and has the concentration gradient with which the p-type impurity concentration decreases from the third high concentration region 68H toward the third low concentration region 68L.

If an intermediate value between the maximum value of the p-type impurity concentration and a minimum value of the p-type impurity concentration is set in the outer contact region 68, the third high concentration region 68H is a region between the maximum value of the p-type impurity concentration and the intermediate value of the p-type impurity concentration. On the other hand, the third low concentration region 68L is a region between the intermediate value of the p-type impurity concentration and the minimum value of the p-type impurity concentration.

A maximum value and a minimum value of the p-type impurity concentration of the third high concentration region 68H are higher than the p-type impurity concentration of the outer well region 67. The maximum value of the p-type impurity concentration of the third high concentration region 68H may be not less than 1.0×10¹⁹ cm⁻³ and not more than 1.0×10²¹ cm⁻³. The p-type impurity concentration of the third high concentration region 68H is preferably substantially equal to the p-type impurity concentration of the first high concentration region 51H. The third high concentration region 68H extends in a band shape (in this embodiment, an annular shape) along the outer side surface 9 in plan view and is exposed from the outer surface 9.

A maximum value and a minimum value of the p-type impurity concentration of the third low concentration region 68L are not more than the minimum value of the first high concentration region 51H but higher than the maximum value of the p-type impurity concentration of the outer well region 67. The minimum value of the p-type impurity concentration of the third low concentration region 68L is preferably not less than 1/1000 and not more than ½ of the maximum value of the p-type impurity concentration of the third high concentration region 68H.

The minimum value of the p-type impurity concentration of the third low concentration region 68L may be not less than 1.0×10¹⁷ cm⁻³ and not more than 1.0×10²⁰ cm⁻³. The p-type impurity concentration of the third low concentration region 68L is preferably substantially equal to the p-type impurity concentration of the first low concentration region 51L. The third low concentration region 68L extends in a band shape (in this embodiment, an annular shape) along the outer side surface 9 in plan view.

The third low concentration region 68L may have a thickness of not less than a thickness of the third high concentration region 68H or may have a thickness less than the thickness of the third high concentration region 68H. That is, with respect to a thickness direction intermediate portion of the outer well region 67, a boundary portion between the third high concentration region 68H and the third low concentration region 68L may be positioned at the outer side surface 9 side or may be positioned at the bottom portion side of the outer well region 67. In consideration of the contact resistance, it is preferable to form the third high concentration region 68H thickly. That is, the third low concentration region 68L preferably has a thickness less than the thickness of the third high concentration region 68H.

The SiC semiconductor device 1A includes at least one (preferably not less than two and not more than twenty) of a field region 69 of the p-type that is formed in a region in the surface layer portion of the outer surface 9 between a peripheral edge of the outer surface 9 and the outer well region 67. In this embodiment, the SiC semiconductor device 1A includes four field regions 69. The plurality of field regions 69 are formed in an electrically floating state and relax an electric field inside the chip 2 at the outer surface 9.

A number, width, depth, p-type impurity concentration, etc., of the field regions 69 are arbitrary and can take on various values in accordance with the electric field to be relaxed. The plurality of field regions 69 may have a lower p-type impurity concentration than the outer contact region 68. The plurality of field regions 69 may have a higher p-type impurity concentration than the outer well region 67. The plurality of field regions 69 may have a lower p-type impurity concentration than the outer well region 67. The p-type impurity concentration (maximum value) of the field regions 69 may be not less than 1.0×10¹⁶ cm⁻³ and not more than 1.0×10²¹ cm⁻³.

The plurality of field regions 69 are arrayed at intervals to the peripheral edge side of the outer surface 9 from the outer contact region 68 side. The plurality of field regions 69 are formed in band shapes extending along the active surface 8 in plan view. In this embodiment, the plurality of field regions 69 are formed in annular shapes (specifically, quadrangle annular shapes) surrounding the active surface 8 in plan view.

The plurality of field regions 69 are formed at an interval to the outer surface 9 side from the bottom portion of the first semiconductor region 6 and oppose the second semiconductor region 7 with a portion of the first semiconductor region 6 interposed therebetween. The plurality of field regions 69 are positioned further to the bottom portion side of the first semiconductor region 6 than the bottom walls 23 of the plurality of second trench structures 20. Bottom portions of the plurality of field regions 69 are positioned further to the bottom portion side of the first semiconductor region 6 than the bottom portions (the bottom portions of the second region 52) of the contact regions 50. The bottom portions of the plurality of field regions 69 may be formed at substantially the same depth position as the bottom portions of the well regions 41.

The SiC semiconductor device 1A includes a main surface insulating film 70 that covers the first main surface 3. The main surface insulating film 70 has a laminated structure including a first main surface insulating film 71 and a second main surface insulating film 72. The first main surface insulating film 71 covers the active surface 8, the outer surface 9, and the first to fourth connecting surfaces 10A to 10D.

On the active surface 8, the first main surface insulating film 71 is continuous to the first insulating film 17 and the third insulating film 38 and exposes the first embedded electrode 18, the second embedded electrodes 27, and the third embedded electrode 39. On the outer surface 9 and the first to fourth connecting surfaces 10A to 10D, the main surface insulating film 70 covers the outer contact region 68, the outer well region 67, and the plurality of field regions 69.

The first main surface insulating film 71 may be continuous to the first to fourth side surfaces 5A to 5D. In this case, an outer wall of the first main surface insulating film 71 may consist of a ground surface with grinding marks. The outer wall of the first main surface insulating film 71 may form a single ground surface with the first to fourth side surfaces 5A to 5D. As a matter of course, the outer wall of the first main surface insulating film 71 may consist of a smooth surface without a grinding mark. Also, the outer wall of the first main surface insulating film 71 may be formed at an interval inward from the peripheral edge of the outer surface 9 and expose the first semiconductor region 6 from a peripheral edge portion of the outer surface 9.

The first main surface insulating film 71 may include at least one among a silicon oxide film, a silicon nitride film, and a silicon oxynitride film. In this embodiment, the first main surface insulating film 71 has a single layer structure consisting of the silicon oxide film. The first main surface insulating film 71 particularly preferably includes the silicon oxide film that consists of the oxide of the chip 2.

The second main surface insulating film 72 covers the active surface 8, the outer surface 9, and the first to fourth connecting surfaces 10A to 10D with the first main surface insulating film 71 interposed therebetween. On the active surface 8, the second main surface insulating film 72 covers the first trench structure 15 and the third trench structure 30. On the outer surface 9 and the first to fourth connecting surfaces 10A to 10D, the second main surface insulating film 72 covers the outer contact region 68, the outer well region 67, and the plurality of field regions 69.

In this embodiment, the second main surface insulating film 72 is continuous to the first to fourth side surfaces 5A to 5D. An outer wall of the second main surface insulating film 72 may consist of a ground surface with grinding marks. The outer wall of the second main surface insulating film 72 may forma single ground surface with the first to fourth side surfaces 5A to 5D. As a matter of course, the outer wall of the second main surface insulating film 72 may consist of a smooth surface without a grinding mark. Also, the outer wall of the second main surface insulating film 72 may be formed at an interval inward from the peripheral edge of the outer surface 9 and expose the first semiconductor region 6 from the peripheral edge portion of the outer surface 9.

The second main surface insulating film 72 may include at least one among a silicon oxide film, a silicon nitride film, and a silicon oxynitride film. In this embodiment, the second main surface insulating film 72 has a single layer structure consisting of the silicon oxide film.

The SiC semiconductor device 1A includes a side wall structure 73 that is arranged inside the main surface insulating film 70 such as to cover at least one of the first to fourth connecting surfaces 10A to 10D on the outer surface 9. Specifically, the side wall structure 73 is arranged on the first main surface insulating film 71 and is covered by the second main surface insulating film 72. In this embodiment, the side wall structure 73 is formed in an annular shape (specifically, a quadrangle annular shape) surrounding the active surface 8 in plan view. The side wall structure 73 may contain an inorganic insulator or a polysilicon.

The SiC semiconductor device 1A includes one or a plurality (in this embodiment, one) of a first gate opening 74 that is formed in the main surface insulating film 70. The first gate opening 74 exposes the pad portion 15a of the first trench structure 15. The SiC semiconductor device 1A includes one or a plurality (in this embodiment, one) of a second gate opening 75 that is formed in the main surface insulating film 70. The second gate opening 75 extends in a band shape along the line portion 15b of the first trench structure 15 and exposes the first embedded electrode 18 of the line portion 15b.

The SiC semiconductor device 1A includes a plurality of source openings 76 that are formed at intervals in the main surface insulating film 70. The plurality of source openings 76 each expose the corresponding second trench structure 20, the corresponding first mesa portion 24, and the corresponding second mesa portion 31. The plurality of source openings 76 each expose the second high concentration region 53H of the contact region 50 from the corresponding first mesa portion 24 and expose the source region 40 and the first high concentration region 51H of the contact region 50 from the corresponding second mesa portion 31. In this embodiment, each source opening 76 is formed in a quadrangle shape in plan view.

The SiC semiconductor device 1A includes one or a plurality (in this embodiment, one) of an outer opening 77 that is formed in the main surface insulating film 70. The outer opening 77 extends in a band shape or an annular shape along the outer contact region 68 and exposes the outer contact region 68. Specifically, the outer opening 77 exposes the third high concentration region 68H of the outer contact region 68.

The SiC semiconductor device 1A includes a gate electrode 80 that is arranged on the main surface insulating film 70. The gate electrode 80 may be referred to as a “gate main surface electrode.” The gate electrode 80 includes a gate pad electrode 81 and a gate line electrode 82. The gate pad electrode 81 is arranged on the pad portion 15a of the first trench structure 15 at an interval from the peripheral edge of the active surface 8. In this embodiment, the gate pad electrode 81 is formed in a quadrangle shape in plan view. The gate pad electrode 81 enters into the first gate opening 74 from above the main surface insulating film 70 and is electrically connected to the first embedded electrode 18 of the pad portion 15a.

The gate line electrode 82 is drawn out onto the line portion 15b of the first trench structure 15 from the gate pad electrode 81. In this embodiment, the gate line electrode 82 covers the line portion 15b at an interval from the peripheral edge of the active surface 8. The gate line electrode 82 is formed in a band shape extending along the line portion 15b in plan view.

In this embodiment, the gate line electrode 82 extends along the first to third side surfaces 5A to 5C (first to third connecting surfaces 10A to 10C) and has a pair of open ends 83 at portions along the fourth side surface 5D (fourth connecting surface 10D). The gate line electrode 82 enters into the second gate opening 75 from above the main surface insulating film 70 and is electrically connected to the first embedded electrode 18 of the line portion 15b.

The gate electrode 80 may include at least one type among a Ti film, a TiN film, a W film, an Al film, a Cu film, an Al alloy film, a Cu alloy film and a conductive polysilicon film. The gate electrode 80 may include at least one of a pure Cu film (a Cu film with a purity of not less than 99%), a pure Al film (an Al film with a purity of not less than 99%), an AlCu alloy film, an AlSi alloy film and an AlSiCu alloy film. In this embodiment, the gate electrode 80 has a laminated structure that includes a Ti film, a TiN film, and an Al alloy film (in this embodiment, an AlCu alloy film) laminated in that order from the chip 2 side.

The SiC semiconductor device 1A includes a source electrode 85 arranged on the main surface insulating film 70 at an interval from the gate electrode 80. The source electrode 85 may be referred to as a “source main surface electrode.” The source electrode 85 includes a source pad electrode 86 and a source line electrode 87.

The source pad electrode 86 is arranged in a region on the main surface insulating film 70 demarcated by the gate pad electrode 81 and the gate line electrode 82 and covers the plurality of second trench structures 20 and the third trench structures 30. The source pad electrode 86 is formed in a polygonal shape that has a concave portion recessed in a concave shape along the gate pad electrode 81 in plan view.

The source pad electrode 86 covers the plurality of third trench structures 30 with the main surface insulating film 70 interposed therebetween and enters into the plurality of source openings 76 from above the main surface insulating film 70. The source pad electrode 86 is electrically connected to the second embedded electrode 27 of the corresponding second trench structure 20, the corresponding first mesa portion 24, and the corresponding second mesa portion 31 inside the corresponding source opening 76.

The source pad electrode 86 is electrically connected to the third region 53 (second high concentration region 53H) of the contact region 50 in the corresponding first mesa portion 24 and is electrically connected to the source region 40 and the first region 51 (first high concentration region 51H) of the contact region 50 in the corresponding second mesa portion 31.

The source line electrode 87 is drawn out in a band shape onto the outer surface 9 from the source pad electrode 86. Specifically, the source line electrode 87 passes through a region between the pair of open ends 83 of the gate line electrode 82 from the source pad electrode 86 and is drawn out onto the outer surface 9. The source line electrode 87 has, in a region between the active surface 8 and the outer surface 9, a portion opposing the side wall structure 73 with the second main surface insulating film 72 interposed therebetween.

The source line electrode 87 extends in a band shape along the outer contact region 68 in plan view. In this embodiment, the source line electrode 87 is formed in an annular shape (specifically, a quadrangle annular shape) surrounding the gate pad electrode 81, the gate line electrode 82, and the source pad electrode 86 in plan view. The source line electrode 87 enters into the outer opening 77 from above the main surface insulating film 70 and is electrically connected to the third high concentration region 68H of the outer contact region 68.

The source electrode 85 may include at least one type among a Ti film, a TiN film, a W film, an Al film, a Cu film, an Al alloy film, a Cu alloy film and a conductive polysilicon film. The source electrode 85 may include at least one of a pure Cu film (a Cu film with a purity of not less than 99%), a pure Al film (an Al film with a purity of not less than 99%), an AlCu alloy film, an AlSi alloy film and an AlSiCu alloy film. In this embodiment, the source electrode 85 has a laminated structure that includes a Ti film and an Al alloy film (in this embodiment, an AlSiCu alloy film) laminated in that order from the chip 2 side. That is, the source electrode 85 contains the same conductive materials as the gate electrode 80.

The SiC semiconductor device 1A includes a drain electrode 88 that covers the second main surface 4. The drain electrode 88 is electrically connected to the second main surface 4. The drain electrode 88 forms an ohmic contact with the second semiconductor region 7 that is exposed from the second main surface 4. The drain electrode 88 may cover a whole region of the second main surface 4 such as to be continuous with the peripheral edge of the chip 2 (first to fourth side surfaces 5A to 5D). A breakdown voltage that can be applied between the source electrode 85 and the drain electrode 88 may be not less than 500 V and not more than 3000 V.

As described above, the SiC semiconductor device 1A includes the chip 2, the second trench structures 20 (trench structures), and the contact regions 50 of the p-type. The chip 2 includes the SiC monocrystal and has the first main surface 3. Each second trench structure 20 has the outer side wall 22 (side wall) and the bottom wall 23 and is formed in the first main surface 3. Each contact region 50 includes the first regions 51 and the second regions 52. The first regions 51 are formed in regions in a surface layer portion of the first main surface 3 along the outer side wall 22. The second regions 52 have the p-type impurity concentration lower than the p-type impurity concentration of the first regions 51 and are formed in regions inside the chip 2 along the bottom wall 23.

As one method for reducing the contact resistance due to the contact region 50, it may be considered to make the contact region 50 high in impurity concentration. For example, in the contact region 50, by making both the regions along the surface layer portion of the first main surface 3 and the regions along the bottom wall 23 of the second trench structure 20 high in impurity concentration, the contact resistance can be reduced effectively.

However, if the contact region 50 is made high in impurity concentration in the regions along the bottom wall 23 of the second trench structure 20, a crystal defect of the SiC monocrystal is at times generated due to modification of the SiC monocrystal in accompaniment with the making of the contact region 50 high in impurity concentration. Electrical characteristics of an SiC semiconductor device are degraded by this type of crystal defect. In particular, the electrical characteristics of the SiC semiconductor device are easily affected by the crystal defect in the regions along the bottom wall 23 of the second trench structure 20.

On the other hand, the contact region 50 of the SiC semiconductor device 1A has the first regions 51 of comparatively high impurity concentration at the surface layer portion side of the first main surface 3 and the second regions 52 that are lower in impurity concentration than the first regions 51 at the bottom wall 23 side of the second trench structure 20. Thereby, the crystal defect with the second region 52 as a starting point can be suppressed in the regions inside the chip 2 along the bottom wall 23 while reducing the contact resistance by the first region 51. The SiC semiconductor device 1A that can be improved in electrical characteristics can thus be provided.

For example, by suppressing the crystal defect, a leak current due to the crystal defect can be suppressed. For example, suppression of the crystal defect is effective in terms of suppressing a zero gate voltage drain current IDSS. The zero gate voltage drain current IDSS is a leak current that flows between a drain and a source in a state where a gate and the source are short circuited. Also, by suppressing the crystal defect, an increase in resistance value due to the crystal defect can be suppressed. For example, the suppression of the crystal defect is effective in terms of suppressing an on resistance Ron.

Each first region 51 preferably includes the first high concentration region 51H and the first low concentration region 51L. The first high concentration region 51H is positioned at the first main surface 3 side and has the comparatively high p-type impurity concentration. The first low concentration region 51L has the p-type impurity concentration lower than the p-type impurity concentration of the first high concentration region 51H and is positioned at the bottom portion side. In this case, each second region 52 preferably has the p-type impurity concentration lower than the p-type impurity concentration of the first high concentration region 51H. According to this structure, the making of the second regions 52 high in impurity concentration can be suppressed appropriately while making the first regions 51 high in impurity concentration appropriately.

The SiC semiconductor device 1A preferably includes the body region 12 of the p-type that is formed in the surface layer portion of the first main surface 3. In this case, the second trench structures 20 are formed in the first main surface 3 such as to penetrate through the body region 12. The first regions 51 preferably have the p-type impurity concentration higher than the p-type impurity concentration of the body region 12 and are formed in the surface layer portion of the body region 12. Also, the second regions 52 preferably have the p-type impurity concentration higher than the p-type impurity concentration of the body region 12.

The SiC semiconductor device 1A preferably includes the well regions 41 of the p-type that are formed in regions inside the chip 2 along the bottom wall 23. In this case, each first region 51 preferably has the p-type impurity concentration higher than the p-type impurity concentration of each well region 41. Also, each second region 52 preferably has the p-type impurity concentration higher than the p-type impurity concentration of each well region 41 and is formed in the region inside the well region 41 along the bottom wall 23. According to these structures, a breakdown voltage can be improved by making use of a depletion layer spreading with the well region 41 as a starting point while suppressing the crystal defect with the contact region 50 as a starting point.

Each contact region 50 preferably includes the first connection regions 54 that are formed in the regions inside the chip 2 along the outer side wall 22 such as to connect the first regions 51 and the second regions 52. According to this structure, the contact resistance can be reduced in regions between the first regions 51 and the second regions 52. The first connection regions 54 preferably have the p-type impurity concentration lower than the p-type impurity concentration of the first regions 51. According to this structure, the crystal defect with the first connection region 54 as a starting point can be suppressed.

The thickness of the first connection region 54 on the basis of the outer side wall 22 is preferably less than the thickness of the first region 51 on a basis of the first main surface 3. The thickness of the first connection region 54 on the basis of the outer side wall 22 is preferably less than the thickness of the second region 52 on the basis of the bottom wall 23.

The chip 2 preferably includes the SiC monocrystal that consists of a hexagonal crystal. According to this structure, a crystal defect (so-called m-plane defect) that is generated along an m-plane of the SiC monocrystal with the second region 52 as a starting point can be suppressed. For example, by suppressing the m-plane defect, a leak current due to the m-plane defect can be suppressed appropriately. For example, suppression of the m-plane defect is particularly effective in terms of suppressing a zero gate voltage drain current IDSS due to the m-plane defect.

Also, according to this structure, a crystal defect (so-called a-plane defect) that is generated along an a-plane of the SiC monocrystal with the second region 52 as a starting point can be suppressed. For example, by suppressing the a-plane defect, an increase in resistance value due to the a-plane defect can be suppressed appropriately. For example, suppression of the a-plane defect is effective in terms of suppressing an increase in the on resistance Ron due to the a-plane defect. The increase in leak current due to the m-plane defect and the increase in resistance value due to the a-plane defect are due to physical properties of the SiC monocrystal.

In this case, the outer side wall 22 preferably includes the first outer side walls 22A extending in the a-axis direction of the SiC monocrystal and the second outer side walls 22B extending in the m-axis direction of the SiC monocrystal. That is, preferably, the first outer side walls 22A are formed by m-planes of the SiC monocrystal and the second outer side walls 22B are formed by a-planes of the SiC monocrystal.

At least one first region 51 may be formed on either or both of a first outer side wall 22A and a second outer side wall 22B. When the at least one first region 51 is formed in a region along a first outer side wall 22A, the first region 51 is preferably formed in the region along the first outer side wall 22A at intervals in the a-axis direction from the second outer side walls 22B.

According to this structure, a formation area of the first region 51 along the outer side wall 22 can be reduced. An m-plane defect and an a-plane defect each with the first region 51 inside the chip 2 as a starting point can thus be suppressed. Such a structure is particularly effective in terms of suppressing the a-plane defect with the first region 51 as the starting point in regions inside the chip 2 along the second outer side walls 22B.

When the at least one first region 51 is formed in a region along a second outer side wall 22B, the first region 51 is preferably formed in the region along the second outer side wall 22B at intervals in the m-axis direction from the first outer side walls 22A.

According to this structure, the formation area of the first region 51 along the outer side wall 22 can be reduced. The m-plane defect and the a-plane defect each with the first region 51 as the starting point can thus be suppressed in regions inside the chip 2 along the outer side wall 22. Such a structure is particularly effective in terms of suppressing the m-plane defect with the first region 51 as the starting point in regions inside the chip 2 along the first outer side walls 22A.

A second region 52 is preferably formed in a region along the bottom wall 23 at intervals in the a-axis direction from the second outer side walls 22B. According to this structure, a formation area of the second region 52 along the bottom wall 23 can be reduced. The m-plane defect and the a-plane defect each with the second region 52 as the starting point can thus be suppressed in regions inside the chip 2 along the bottom wall 23. Such a structure is particularly effective in terms of suppressing the a-plane defect with the second region 52 as the starting point in regions inside the chip 2 along the second outer side walls 22B.

A second region 52 is preferably formed in a region along the bottom wall 23 at intervals in the m-axis direction from the first outer side walls 22A. According to this structure, the formation area of the second region 52 along the bottom wall 23 can be reduced. The m-plane defect and the a-plane defect each with the second region 52 as the starting point can thus be suppressed in regions inside the chip 2 along the bottom wall 23. Such a structure is particularly effective in terms of suppressing the m-plane defect with the second region 52 as the starting point in regions inside the chip 2 along the first outer side walls 22A.

At least one first connection region 54 may be formed on either or both of a first outer side wall 22A and a second outer side wall 22B. When the at least one first connection region 54 is formed in a region along a first outer side wall 22A, the first connection region 54 is preferably formed in the region along the first outer side wall 22A at intervals in the a-axis direction from the second outer side walls 22B.

According to this structure, a formation area of the first connection region 54 along the outer side wall 22 can be reduced. An m-plane defect and an a-plane defect each with the first connection region 54 inside the chip 2 as a starting point can thus be suppressed. Such a structure is particularly effective in terms of suppressing the a-plane defect with the first connection region 54 as the starting point in regions inside the chip 2 along the second outer side walls 22B.

When the at least one first connection region 54 is formed in a region along a second outer side wall 22B, the first connection region 54 is preferably formed in the region along the second outer side wall 22B at intervals in the m-axis direction from the first outer side walls 22A.

According to this structure, the formation area of the first connection region 54 along the outer side wall 22 can be reduced. The m-plane defect and the a-plane defect each with the first connection region 54 as the starting point can thus be suppressed in regions inside the chip 2 along the outer side wall 22. Such a structure is particularly effective in terms of suppressing the a-plane defect with the first connection region 54 as the starting point in regions inside the chip 2 along the first outer side walls 22A.

Each second trench structure 20 may be formed in an annular shape in plan view. The second trench structure 20 preferably has the first bottom walls 23A that extend in band shapes in the a-axis direction and the second bottom walls 23B that extend in band shapes in the m-axis direction. In this case, at least one second region 52 may be formed on either or both of a first bottom wall 23A and a second bottom wall 23B.

When the at least one second region 52 is formed in a region along a second bottom wall 23B, the second region 52 is preferably formed in the region along the second bottom wall 23B at intervals in the m-axis direction from the first bottom walls 23A. According to this structure, a formation area of the second region 52 along the bottom wall 23 can be reduced. An m-plane defect and an a-plane defect each with the second region 52 as a starting point can thus be suppressed. Such a structure can suppress the m-plane defect with the second region 52 as the starting point in regions inside the chip 2 along the first bottom walls 23A.

When the at least one second region 52 is formed in a region along a first bottom wall 23A, the second region 52 is preferably formed in the region along the first bottom wall 23A at intervals in the a-axis direction from the second bottom walls 23B. According to this structure, the formation area of the second region 52 along the bottom wall 23 can be reduced. The m-plane defect and the a-plane defect each with the second region 52 as the starting point can thus be suppressed. Such a structure can suppress the a-plane defect with the second region 52 as the starting point in regions inside the chip 2 along the second bottom walls 23B.

The SiC semiconductor device 1A may include the first mesa portions 24 demarcated in the first main surface 3 by the second trench structures 20. In this case, each contact region 50 preferably has the third region 53 positioned in the surface layer portion of the first main surface 3 in the first mesa portion 24. According to this structure, the formation region of the contact region 50 can be expanded using the first mesa portion 24. The contact resistance can thus be reduced while suppressing the crystal defect with the second region 52 as the starting point.

The SiC semiconductor device 1A preferably includes the third trench structure 30 that is formed in the first main surface 3 at intervals from the second trench structures 20. In this case, the SiC semiconductor device 1A preferably includes the source regions 40 of the n-type that are formed in regions along the third trench structure 30 in the surface layer portion of the first main surface 3.

The third trench structure 30 may be formed in the first main surface 3 such as to extend in the a-axis direction at intervals in the m-axis direction from the first outer side walls 22A of the second trench structures 20. The third trench structure 30 may be formed in the first main surface 3 such as to extend in the m-axis direction at intervals in the a-axis direction from the second outer side walls 22B of the second trench structures 20. The third trench structure 30 may be formed in annular shapes surrounding the second trench structures 20 in plan view. According to these structures, the crystal defect with the second region 52 as the starting point can be suppressed in regions between the second trench structures 20 and the third trench structure 30.

In another aspect, the SiC semiconductor device 1A, as described above, includes the chip 2, the second trench structures 20 (trench structures), and the contact regions 50 of the p-type. The chip 2 includes the SiC monocrystal and has the first main surface 3. Each second trench structure 20 has the inner side wall 21 (side wall) and the bottom wall 23 and is formed in the first main surface 3. Each contact region 50 includes the third region 53 and the second regions 52. The third region 53 is formed in a region in a surface layer portion of the first main surface 3 along the inner side wall 21. The second regions 52 have the p-type impurity concentration lower than the p-type impurity concentration of the third region 53 and are formed in the regions inside the chip 2 along the bottom wall 23.

According to this structure, the crystal defect with the second region 52 as the starting point can be suppressed in the regions inside the chip 2 along the bottom wall 23 while reducing the contact resistance by the third region 53. The SiC semiconductor device 1A that can be improved in electrical characteristics can thus be provided. For example, by suppressing the crystal defect, the leak current due to the crystal defect can be suppressed. For example, the suppression of the crystal defect is effective in terms of suppressing the zero gate voltage drain current IDSS. Also, by suppressing the crystal defect, the increase in resistance value due to the crystal defect can be suppressed. For example, the suppression of the crystal defect is effective in terms of suppressing the on resistance Ron.

The third region 53 preferably includes the second high concentration region 53H and the second low concentration region 53L. The second high concentration region 53H is positioned at the first main surface 3 side and has the comparatively high p-type impurity concentration. The second low concentration region 53L has the p-type impurity concentration lower than the p-type impurity concentration of the second high concentration region 53H and is positioned at the bottom portion side. In this case, each second region 52 preferably has the p-type impurity concentration lower than the p-type impurity concentration of the second high concentration region 53H. According to this structure, the making of the second regions 52 high in impurity concentration can be suppressed appropriately while making the third region 53 high in impurity concentration appropriately.

In yet another aspect, the SiC semiconductor device 1A may include the chip 2, the first semiconductor region 6 of the n-type, the body region 12 of the p-type, the second trench structures 20 as the trench source structures, the third trench structure 30 as the trench gate structure, the source regions 40 of the n-type, and the contact regions 50 of the p-type. The chip 2 includes the SiC monocrystal and has the first main surface 3. The first semiconductor region 6 is formed in the surface layer portion of the first main surface 3.

The body region 12 is formed in the surface layer portion of the first semiconductor region 6. Each second trench structure 20 has the outer side wall 22 (side wall) and the bottom wall 23 and is formed in the first main surface 3. The third trench structure 30 is formed in the first main surface 3 at intervals from the second trench structures 20 such as to penetrate through the body region 12. The source regions 40 are formed in the regions in the surface layer portion of the body region 12 along the third trench structure 30.

Each contact region 50 includes the first regions 51 and the second regions 52. The first regions 51 are formed in the regions in the surface layer portion of the first main surface 3 along the outer side wall 22 of the second trench structures 20. The second regions 52 have the p-type impurity concentration lower than the p-type impurity concentration of the first regions 51 and are formed in regions inside the chip 2 along the bottom wall 23 of the second trench structures 20.

According to this structure, the crystal defect with the second contact region 52 as the starting point can be suppressed in the regions between the second trench structures 20 and the third trench structure 30. The SiC semiconductor device 1A that can be improved in the electrical characteristics can thereby be provided. For example, by suppressing the crystal defect, the leak current due to the crystal defect can be suppressed. For example, the suppression of the crystal defect is effective in terms of suppressing the zero gate voltage drain current IDSS. Also, by suppressing the crystal defect, the increase in resistance value due to the crystal defect can be suppressed. For example, the suppression of the crystal defect is effective in terms of suppressing the on resistance Ron.

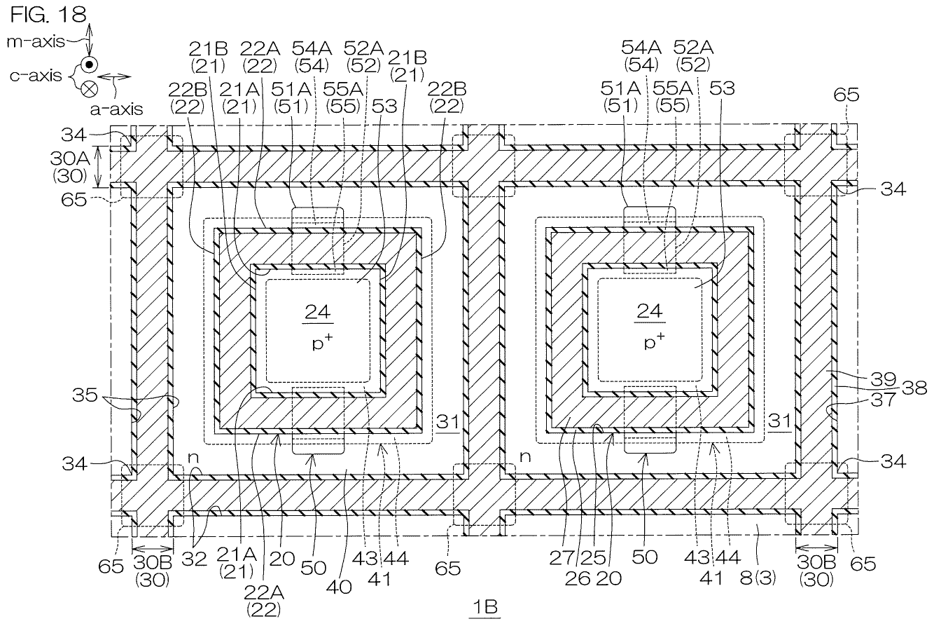

FIG. 18 is a plan view corresponding to FIG. 8 and showing an SiC semiconductor device 1B according to a second embodiment. The SiC semiconductor device 1B is a device that exhibits the same effects as the SiC semiconductor device 1A. The SiC semiconductor device 1A described above includes the contact regions 50 each having the pair of second regions 52A and the pair of second regions 52B.

On the other hand, each contact region 50 of the SiC semiconductor device 1B does not include the pair of second regions 52B. In this case, the contact region 50 preferably does not include at least one or all of the pair of first regions 51B, the pair of first connection regions 54B, and the pair of second connection regions 55B. A distance between the third trench structure 30B and the second region 52A is greater than a distance between the third trench structure 30A and the second region 52A.

According to the SiC semiconductor device 1B, a formation region of each second region 52 can be reduced and the crystal defect with the second region 52 as the starting point can be suppressed. Also, according to this structure, the a-plane defect with the second region 52 as the starting point can be suppressed in the regions between the second trench structures 20 and the third trench structures 30B (regions extending along a-planes of the SiC monocrystal). Such a structure is therefore effective in terms of suppressing the increase in the resistance value (the on resistance) due to the a-plane defect.

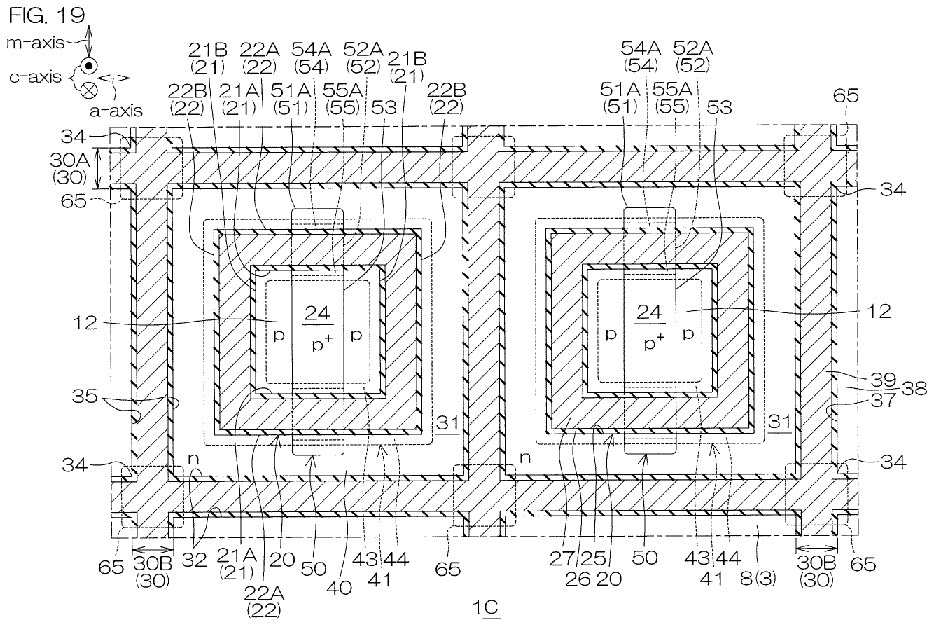

FIG. 19 is a plan view corresponding to FIG. 8 and showing an SiC semiconductor device 1C according to a third embodiment. The SiC semiconductor device 1C has a mode in which the contact regions 50 of the SiC semiconductor device 1B are modified and is a device that exhibits the same effects as the SiC semiconductor device 1B.

Specifically, each contact region 50 of the SiC semiconductor device 1C includes the third region 53 extending in a band shape in the m-axis direction at intervals in the a-axis direction from the pair of second inner side walls 21B. In this case, the contact region 50 preferably does not include the pair of second connection regions 55B. That is, the contact region 50 is preferably formed in a band shape extending in the m-axis direction at intervals in the a-axis direction from the pair of second inner side walls 21B in plan view.

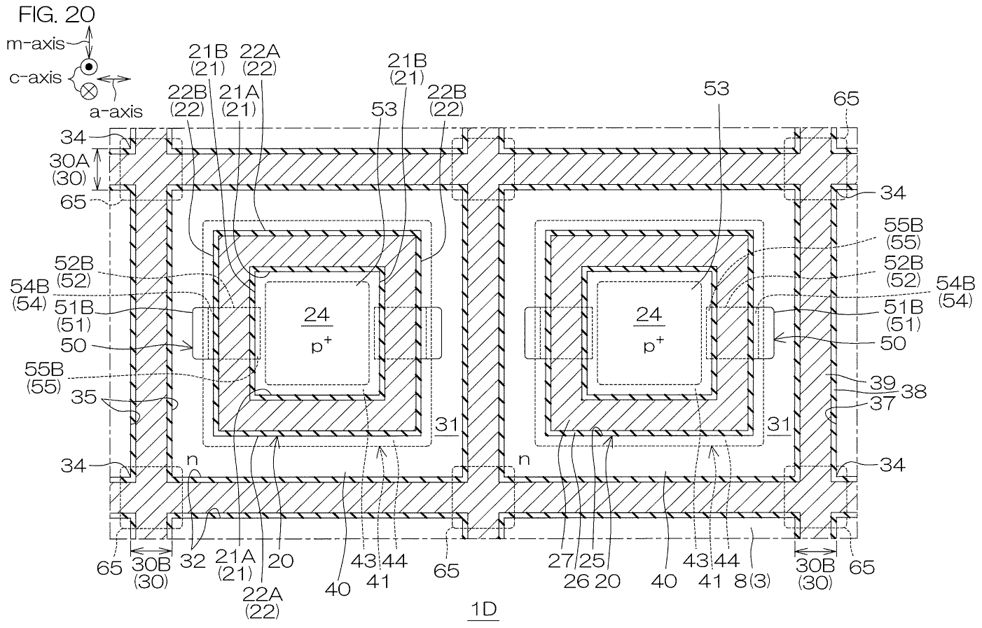

FIG. 20 is a plan view corresponding to FIG. 8 and showing an SiC semiconductor device 1D according to a fourth embodiment. The SiC semiconductor device 1D is a device that exhibits the same effects as the SiC semiconductor device 1A. The SiC semiconductor device 1A described above includes the contact regions 50 each having the pair of second regions 52A and the pair of second regions 52B.

On the other hand, each contact region 50 of the SiC semiconductor device 1D does not include the pair of second regions 52A. In this case, the contact region 50 preferably does not include at least one or all of the pair of first regions 51A, the pair of first connection regions 54A, and the pair of second connection regions 55A. A distance between the third trench structure 30A and the second region 52B is greater than a distance between the third trench structure 30B and the second region 52A.

According to this structure, the formation region of each second region 52 can be reduced and the crystal defect with the second region 52 as the starting point can be suppressed. Also, according to this structure, the m-plane defect with the second region 52 as the starting point can be suppressed in the regions between the second trench structures 20 and the third trench structures 30A (regions extending along m-planes of the SiC monocrystal). Such a structure is therefore effective in terms of suppressing the increase in the leak current (the zero gate voltage drain current IDSS) due to the m-plane defect.

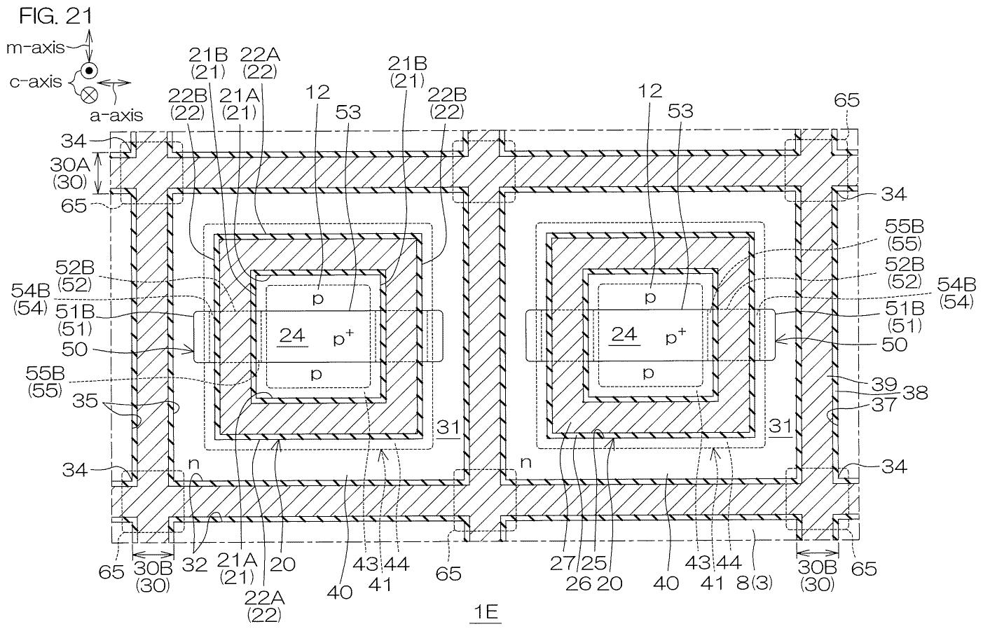

FIG. 21 is a plan view corresponding to FIG. 8 and showing an SiC semiconductor device 1E according to a fifth embodiment. The SiC semiconductor device 1E has a mode in which the contact regions 50 of the SiC semiconductor device 1D are modified and is a device that exhibits the same effects as the SiC semiconductor device 1D. Specifically, each contact region 50 of the SiC semiconductor device 1E includes the third region 53 extending in a band shape in the a-axis direction at intervals in the m-axis direction from the pair of first inner side walls 21A.

In this case, the contact region 50 preferably does not include the pair of second connection regions 55A. That is, the contact region 50 is preferably formed in a band shape extending in the a-axis direction at intervals in the m-axis direction from the pair of first inner side walls 21A in plan view.

The contact regions 50 of the SiC semiconductor device 1E may be formed at the same time as the contact regions 50 of the SiC semiconductor device 1C. In this case, the contact regions 50 each of cross shape having a portion extending in a band shape in the a-axis direction and a portion extending in a band shape in the m-axis direction in plan view are formed.

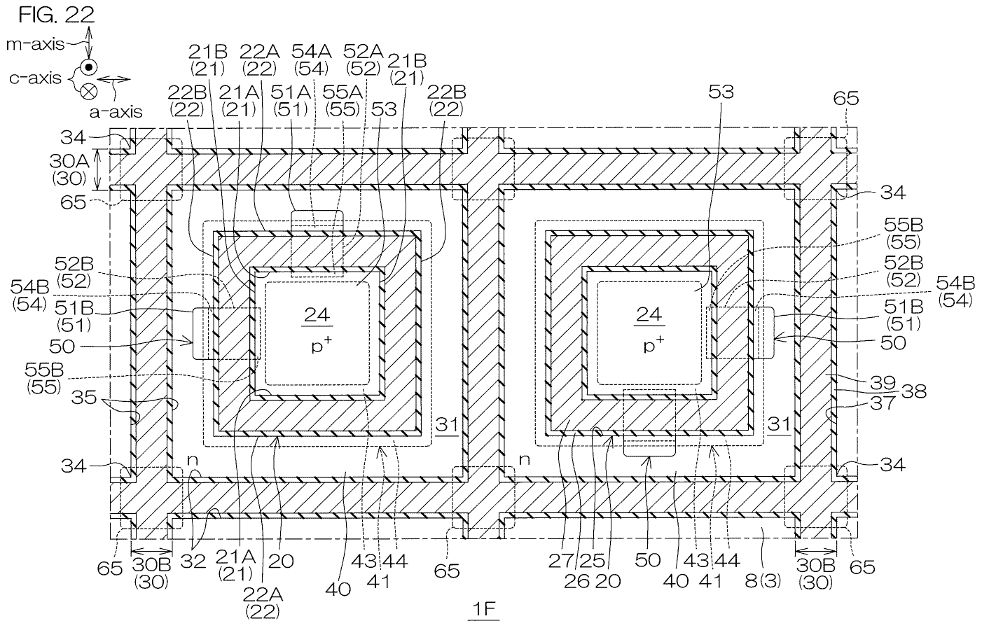

FIG. 22 is a plan view corresponding to FIG. 8 and showing an SiC semiconductor device 1F according to a sixth embodiment. The SiC semiconductor device 1F is a device that exhibits the same effects as the SiC semiconductor device 1A. The SiC semiconductor device 1A described above includes the contact regions 50 each having the pair of second regions 52A and the pair of second regions 52B.

On the other hand, each contact region 50 of the SiC semiconductor device 1F includes the single second region 52A and the single second region 52B. In correspondence to the single second region 52A and the single second region 52B, the contact region 50 includes the single first region 51A, the single first region 51B, the single first connection region 54A, the single first connection region 54B, the single second connection region 55A, and the single second connection region 55B.

The single first connection region 54A connects the single first region 51A and the single second region 52A. The single first connection region 54B connects the single first region 51B and the single second region 52B. The single second connection region 55A connects the single second region 52A and the third region 53. The single second connection region 55B connects the single second region 52B and the third region 53.

In this embodiment, the third region 53 is formed, as in the first embodiment, in the whole region of the surface layer portion of the body region 12 inside the first mesa portion 24. As a matter of course, the third region 53 may extend in an L-shape between the single second region 52A and the single second region 52B in plan view instead.

Looking at one second trench structure 20 and another second structure 20, a formation location of the second region 52A with respect to the one second structure 20 may be the same as or may differ from the formation location of the second region 52A with respect to the other second structure 20. Also, looking at the one second trench structure 20 and the other second structure 20, a formation location of the second region 52B with respect to the one second structure 20 may be the same as or may differ from the formation location of the second region 52B with respect to the other second structure 20.

According to this structure, them-plane defect and the a-plane defect each with the second region 52 as the starting point can be suppressed. Such a structure is effective in terms of suppressing the increase in the resistance value (the on resistance) due to the a-plane defect and suppressing the increase in the leak current (the zero gate voltage drain current IDSS) due to the m-plane defect.

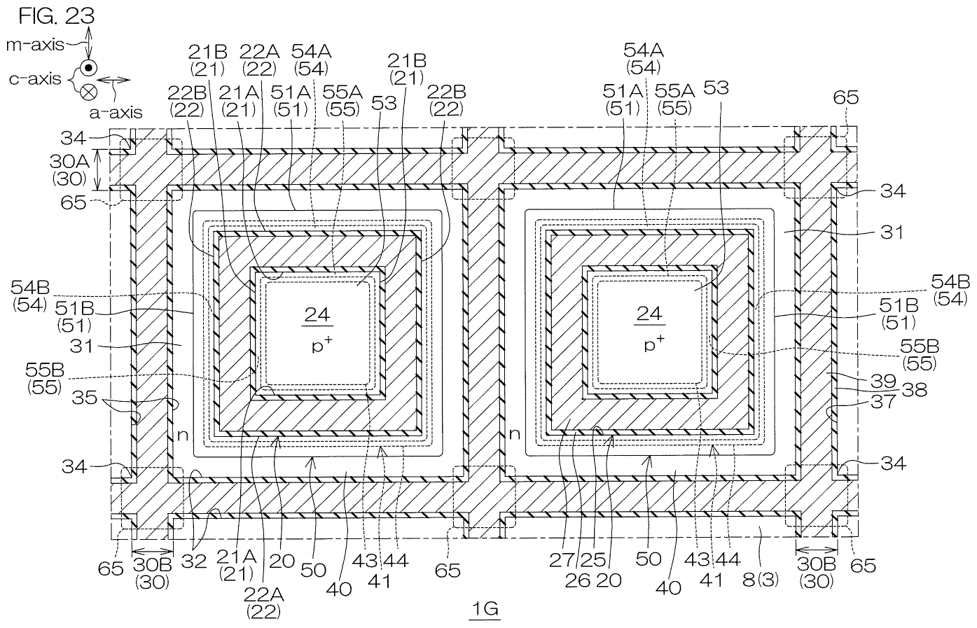

FIG. 23 is a plan view showing an SiC semiconductor device 1G according to a seventh embodiment. The SiC semiconductor device 1G is a device that exhibits the same effects as the SiC semiconductor device 1A. The SiC semiconductor device 1A described above includes the pair of first regions 51A that are formed in regions along portions of the pair of first outer side walls 22A and the pair of first regions 51B that are formed in regions along portions of the pair of second outer side walls 22B.

On the other hand, the SiC semiconductor device 1G includes the pair of first regions 51A that are formed in regions along whole regions of the pair of first outer side walls 22A and the pair of first regions 51B that are formed in regions along whole regions of the pair of second outer side walls 22B. That is, in this embodiment, each contact region 50 includes the single first region 51 that surrounds the outer side wall 22 of the second trench structure 20.

In this case, the contact region 50 may include the pair of second regions 52A that are formed in regions along whole regions of the pair of first bottom walls 23A and the pair of second regions 52B that are formed in regions along whole regions of the pair of second bottom walls 23B. That is, the contact region 50 may include the single second region 52 that is formed in a region along a whole region of the bottom wall 23.

Also, the contact region 50 may include the pair of first connection regions 54A that are formed in regions along the whole regions of the pair of first outer side walls 22A and the pair of first connection regions 54B that are formed in regions along the whole regions of the pair of second outer side walls 22B. That is, the contact region 50 may include the single first connection region 54 that is formed in a region along the whole region of the outer side wall 22.

Also, the contact region 50 may include the pair of second connection regions 55A that are formed in regions along whole regions of the pair of first inner side walls 21A and the pair of second connection regions 55B that are formed in regions along whole regions of the pair of second inner side walls 21B. That is, the contact region 50 may include the single second connection region 55 that is formed in a region along a whole region of the inner side wall 21.

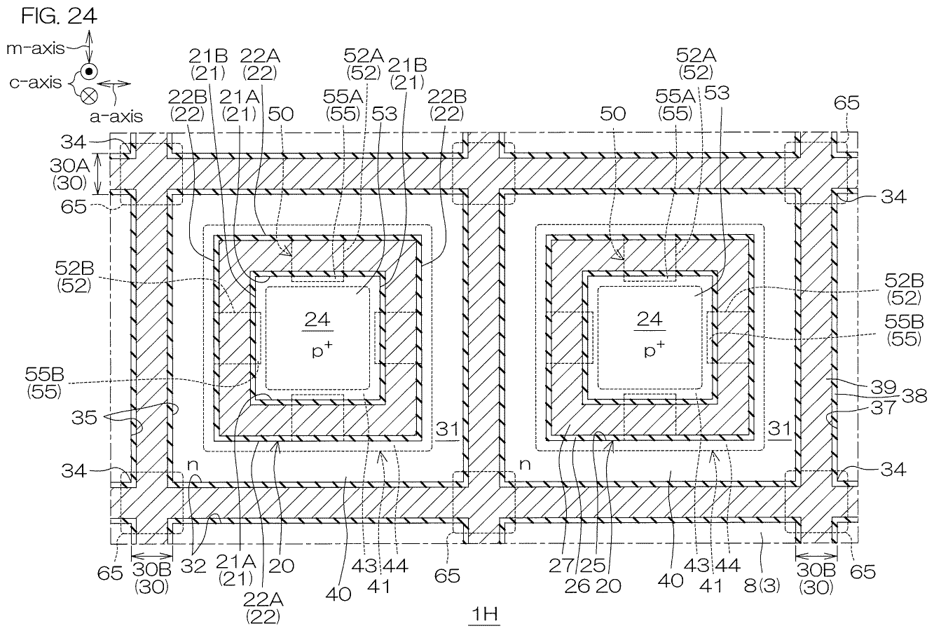

FIG. 24 is a plan view corresponding to FIG. 8 and showing an SiC semiconductor device 1H according to an eighth embodiment. The SiC semiconductor device 1H is a device that exhibits the same effects as the SiC semiconductor device 1A. The SiC semiconductor device 1A described above includes the contact regions 50 each having the first regions 51, the second regions 52, and the third region 53. On the other hand, each contact region 50 of the SiC semiconductor device 1H includes the second regions 52 and the third region 53 but does not include the first regions 51. In this case, the contact region 50 preferably does not include the first connection regions 54.

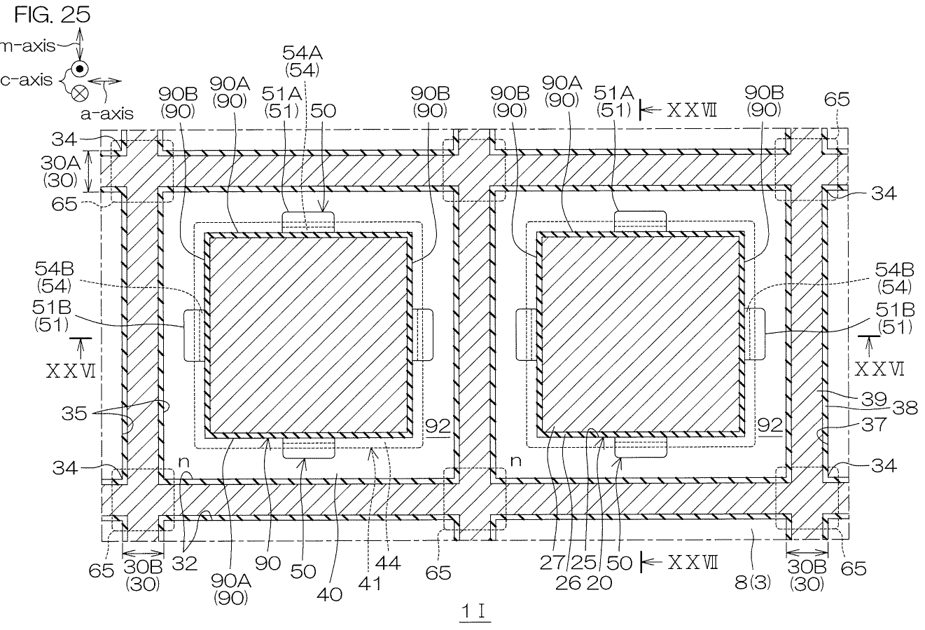

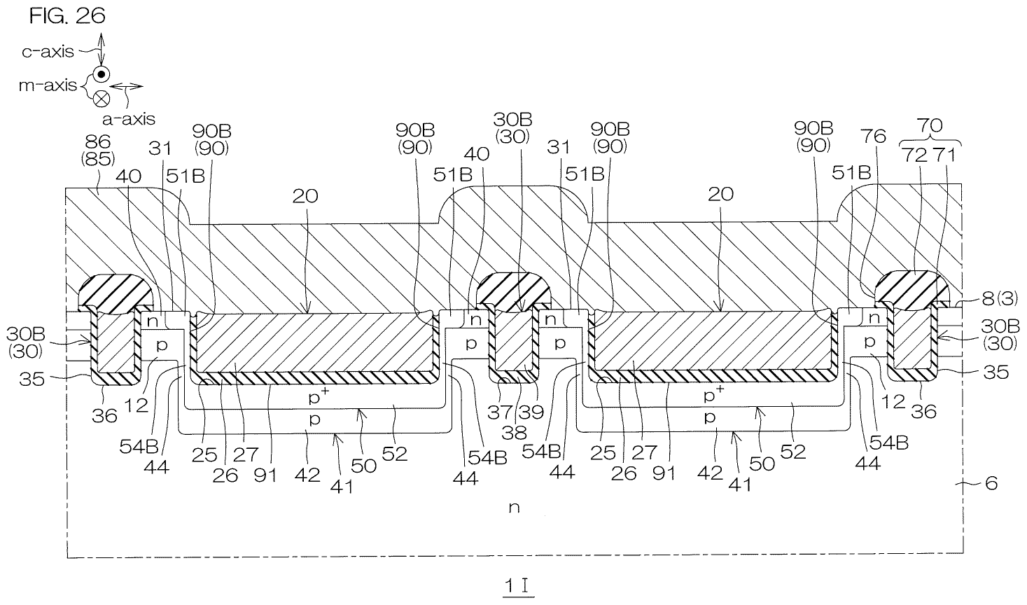

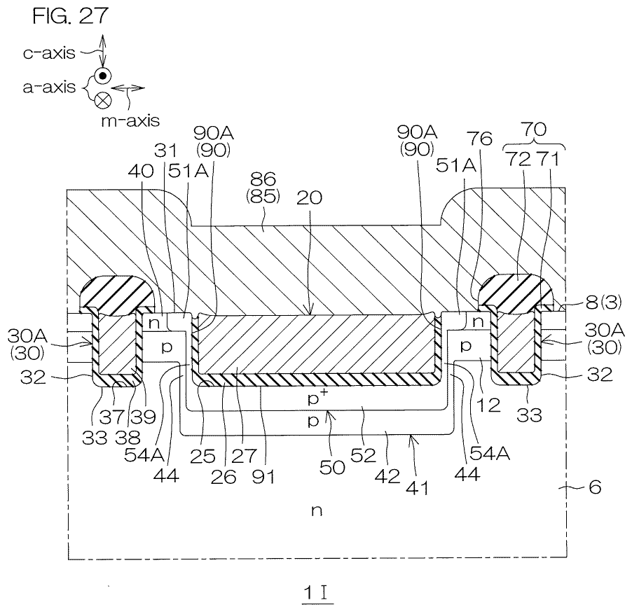

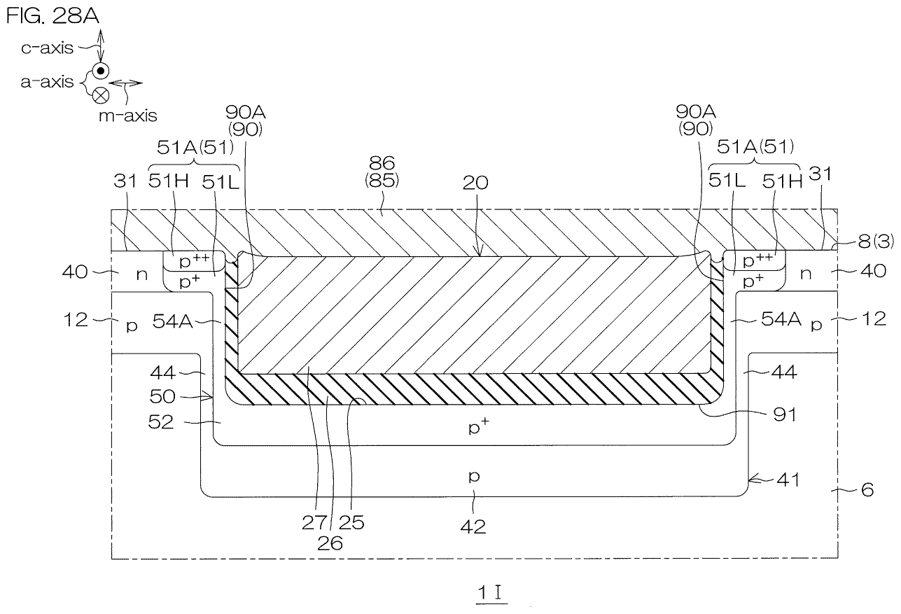

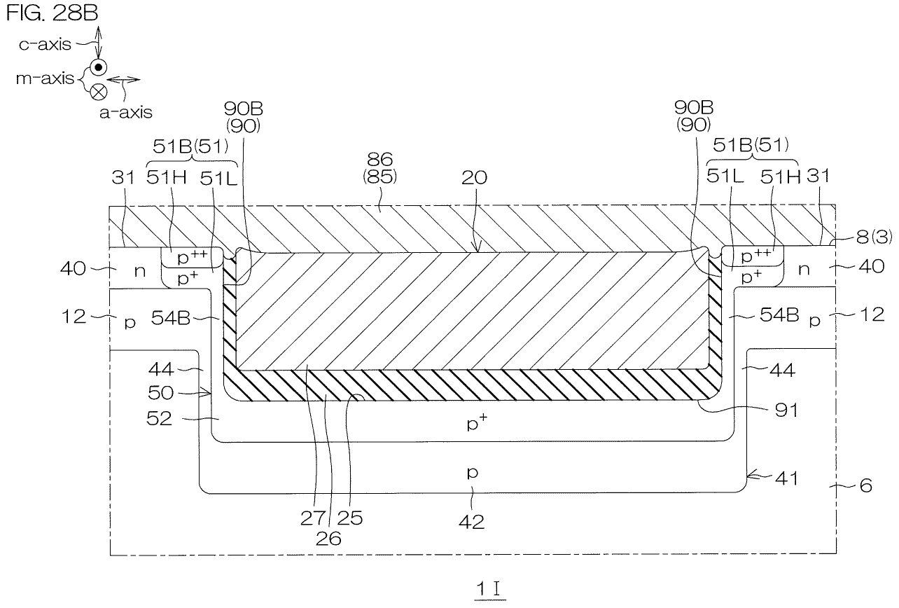

FIG. 25 is a plan view corresponding to FIG. 8 and showing an SiC semiconductor device 1I according to a ninth embodiment. FIG. 26 is a cross sectional view taken along line XXVI-XXVI shown in FIG. 25. FIG. 27 is a cross sectional view taken along line XXVII-XXVII shown in FIG. 25. FIG. 28A is an enlarged cross sectional view showing the arrangement where the region including the second trench structure 20 and the contact region 50 is cut in the m-axis direction. FIG. 28B is an enlarged cross sectional view showing the arrangement where the region including the second trench structure 20 and the contact region 50 is cut in the a-axis direction.

The SiC semiconductor device 1I is a device that exhibits the same effects as the SiC semiconductor device 1A. The SiC semiconductor device 1A described above includes the second trench structures 20 each formed in the annular shape extending in the a-axis direction and the m-axis direction in plan view. On the other hand, the SiC semiconductor device 1I includes the second trench structures 20 each formed in a quadrangle shape having the four sides extending in the a-axis direction and the m-axis direction in plan view. As in the first embodiment, each second trench structure 20 includes the second trench 25, the second insulating film 26, and the second embedded electrode 27.

In this embodiment, each second trench structure 20 includes a side wall 90 and a bottom wall 91. The side wall 90 is formed in a quadrangle shape extending in the a-axis direction and the m-axis direction in plan view. Specifically, the side wall 90 includes a pair of first side walls 90A and a pair of second side walls 90B. The pair of first side walls 90A extend in the a-axis direction and are opposed in the m-axis direction. That is, the pair of first side walls 90A are demarcated by m-planes. The pair of second side walls 90B extend in the m-axis direction such as to be connected to the pair of first side walls 90A and are opposed in the a-axis direction. That is, the pair of second side walls 90B are demarcated by a-planes.

The bottom wall 91 is formed in a quadrangle shape extending flatly along the a-axis direction and the m-axis direction in plan view and connects the pair of first side walls 90A and the pair of second side walls 90B. The bottom wall 91 is formed by a c-plane. If the active surface 8 (first main surface 3) has the off angle inclined in the predetermined off direction at the predetermined angle with respect to the c-plane, the bottom wall 91 may have the off direction and the off angle like the active surface 8 (first main surface 3).

As in the case of the first embodiment, the third trench structure 30 is formed in a lattice pattern (in annular shapes) extending in the a-axis direction and the m-axis direction in the regions between the plurality of second trench structures 20 such as to surround the plurality of second trench structures 20 in plan view. In this embodiment, the third trench structure 30 demarcates, with the side walls 90 of the plurality of second trench structures 20, a plurality of mesa portions 92 that extend in annular shapes (specifically, quadrangle annular shapes).

As in the case of the first embodiment, the third trench structure 30 includes the plurality of third trench structures 30A and the plurality of third trench structures 30B. In this embodiment, the plurality of third trench structures 30A are formed at intervals in the m-axis direction from the plurality of first side walls 90A such as to oppose the plurality of first side walls 90A in the m-axis direction and extend in band shapes in the a-axis direction in regions between the plurality of first side walls 90A. In this embodiment, the plurality of third trench structures 30B are formed at intervals in the a-axis direction from the plurality of second side walls 90B such as to oppose the plurality of second side walls 90B in the a-axis direction and extend in band shapes in the m-axis direction in regions between the plurality of second side walls 90B.

In this embodiment, each well region 41 includes the well bottom wall portion 42 and the second well side wall portion 44 but does not include the first side wall portion 43. The second well side wall portion 44 may be referred to simply as a “well side wall portion.” The well bottom wall portion 42 is formed in a region along the bottom wall 91 of the second trench structure 20. Specifically, the well bottom wall portion 42 covers a whole region of the bottom wall 91. The well bottom wall portion 42 is formed at an interval to the active surface 8 side from the bottom portion of the first semiconductor region 6 and opposes the second semiconductor region 7 with a portion of the first semiconductor region 6 interposed therebetween.

A second well side wall portion 44 is drawn out to the side wall 90 side of the second trench structure 20 from the well bottom wall portion 42 side and is formed in a region along the side wall 90. Specifically, the second well side wall portion 44 is formed in a region in the mesa portion 92 along the pair of first side walls 90A and the pair of second side walls 90B.

The second well side wall portion 44 is formed in an annular shape (specifically, a quadrangle annular shape) surrounding the second trench structure 20 in the mesa portion 92 at an interval from the third trench structure 30. The second well side wall portion 44 is connected to the body region 12 in a surface layer portion of the mesa portion 92. A thickness of the second well side wall portion 44 on a basis of the side wall 90 is less than a thickness of the well bottom wall portion 42 on a basis of the bottom wall 91.

In this embodiment, each contact region 50 includes the first regions 51, the second region 52, and the first connection regions 54 but does not include the third region 53 and the second connection regions 55. The first connection regions 54 may be referred to simply as “connection regions.” As in the first embodiment, the first regions 51 include the pair of first regions 51A and the pair of first regions 51B.

In this embodiment, the pair of first regions 51A are formed in regions of the second trench structure 20 along the pair of first side walls 90A. The pair of first regions 51A are preferably formed to be narrower than the first side walls 90A in the a-axis direction. The pair of first regions 51A are formed in the regions along the pair of first side walls 90A at intervals in the a-axis direction from the pair of second side walls 90B.

The pair of first regions 51A preferably oppose each other in the m-axis direction. The pair of first regions 51A are preferably formed in regions along central portions of the pair of first side walls 90A. As a matter of course, the pair of first regions 51A may be shifted with respect to each other in the a-axis direction such as not to be opposed in the m-axis direction.

The width in the a-axis direction of each first region 51A is preferably not more than ½ of a width in the a-axis direction of the first side walls 90A. The width in the a-axis direction of each first region 51A is particularly preferably not more than ¼ of the width in the a-axis direction of the first side walls 90A. The width in the a-axis direction of each first region 51A may be not less than 1/10 of the width in the a-axis direction of the first side walls 90A.

In this embodiment, the pair of first regions 51B are formed in regions of the second trench structure 20 along the pair of second side walls 90B. The pair of first regions 51B are preferably formed to be narrower than the second side walls 90B in the m-axis direction. The pair of first regions 51B are formed in the regions along the pair of second side walls 90B at intervals in the m-axis direction from the pair of first side walls 90A.

The pair of first regions 51B preferably oppose each other in the a-axis direction. The pair of first regions 51B are preferably formed in regions along central portions of the pair of second side walls 90B. As a matter of course, the pair of first regions 51B may be shifted with respect to each other in the m-axis direction such as not to be opposed in the a-axis direction.

The width in the m-axis direction of each first region 51B is preferably not more than ½ of a width in the m-axis direction of the second side walls 90B. The width in the m-axis direction of each first region 51B is particularly preferably not more than ¼ of the width in the m-axis direction of the second side walls 90B. The width in the m-axis direction of each first region 51B may be not less than 1/10 of the width in the m-axis direction of the second side walls 90B.

As in the first embodiment, each first region 51 includes the first high concentration region 51H at the active surface 8 side and the first low concentration region 51L at the bottom portion side. Other arrangements of the first region 51 are the same as in the case of the first embodiment and therefore, other descriptions concerning the first region 51 shall be omitted.

In this embodiment, the second region 52 covers the whole region of the bottom wall 91 of the second trench structure 20. As in the first embodiment, the second region 52 has the p-type impurity concentration that is less than the p-type impurity concentration of the first regions 51. Other arrangements of the second region 52 are the same as in the case of the first embodiment and therefore, other descriptions concerning the second region 52 shall be omitted.

As in the first embodiment, the first connection regions 54 include the pair of first connection regions 54A and the pair of first connection regions 54B. The pair of first connection regions 54A are each formed in the region along the corresponding first side walls 90A such as to connect the first region 51A and the second region 52 that are adjacent thereto in the up/down direction. The pair of first connection regions 54A are preferably formed to be narrower than the first side walls 90A in the a-axis direction.

The pair of first connection regions 54A are formed in the regions along the first side walls 90A at intervals in the a-axis direction from the pair of second side walls 90B. The pair of first connection regions 54A are preferably formed in regions along the central portions of the pair of first side walls 90A. The formation locations of the pair of first connection regions 54A are adjusted in accordance with the formation locations of the corresponding first regions 51A.

The width in the a-axis direction of each first connection region 54A is preferably not more than ½ of the width in the a-axis direction of the first side walls 90A. The width in the a-axis direction of each first connection region 54A is particularly preferably not more than ¼ of the width in the a-axis direction of the first side walls 90A. The width in the a-axis direction of each first connection region 54A may be not less than 1/10 of the width in the a-axis direction of the first side walls 90A. The width in the a-axis direction of each first connection region 54A is preferably substantially equal to the width in the a-axis direction of each first region 51A.

The pair of first connection regions 54B are each formed in a region along the corresponding second side wall 90B such as to connect the first region 51B and the second region 52 that are adjacent thereto in the up/down direction. The pair of first connection regions 54B are preferably formed to be narrower than the second side walls 90B in the m-axis direction.

The pair of first connection regions 54B are formed in the regions along the pair of second side walls 90B at intervals in the m-axis direction from the pair of first side walls 90A. The pair of first connection regions 54A are preferably formed in regions along the central portions of the pair of second side walls 90B. The formation locations of the pair of first connection regions 54B are adjusted in accordance with the formation locations of the corresponding first regions 51B.

A width in the m-axis direction of each first connection region 54B is preferably not more than ½ of the width in the m-axis direction of the second side walls 90B. The width in the m-axis direction of each first connection region 54B is particularly preferably not more than ¼ of the width in the m-axis direction of the second side walls 90B. The width in the m-axis direction of each first connection region 54B may be not less than 1/10 of the width in the m-axis direction of the second side walls 90B. The width in the m-axis direction of each first connection region 54B is preferably substantially equal to the width in the m-axis direction of each first region 51B.

The thickness of the first connection region 54 on a basis of the side wall 90 is less than the thickness of the first region 51 on the basis of the active surface 8. The thickness of the first connection region 54 on the basis of the side wall 90 is less than the thickness of the second region 52 on the basis of the bottom wall 23 of the second trench structure 20. Other arrangements of the first connection region 54 are the same as in the case of the first embodiment and therefore, other descriptions concerning the first connection region 54 shall be omitted.

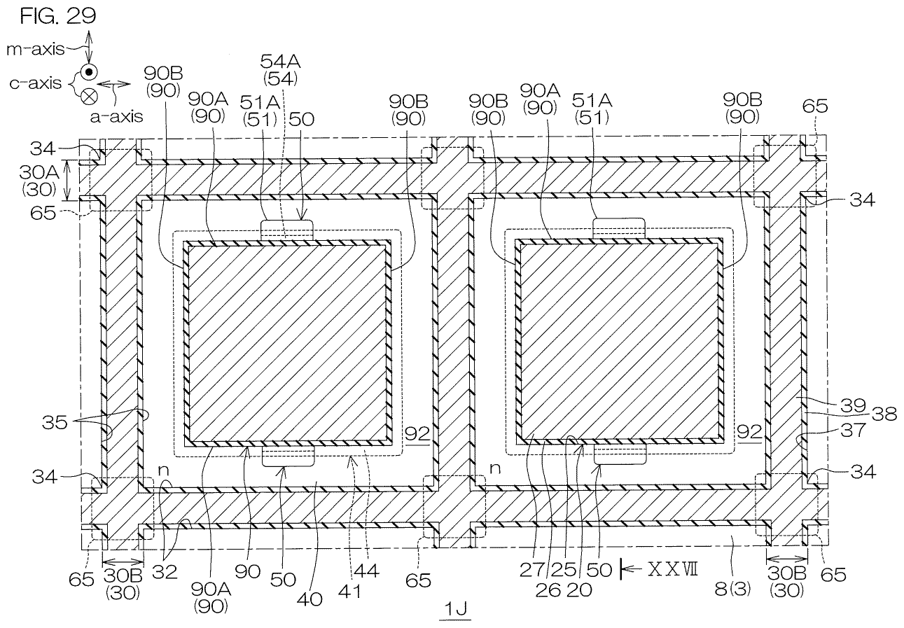

FIG. 29 is a plan view corresponding to FIG. 25 and showing an SiC semiconductor device 1J according to a tenth embodiment. The SiC semiconductor device 1J is a device that exhibits the same effects as the SiC semiconductor device 1I. The SiC semiconductor device 1I described above includes the contact regions 50 each having the pair of first regions 51A and the pair of first regions 51B. On the other hand, each contact region 50 of the SiC semiconductor device 1J does not include the pair of first regions 51B. In this case, the contact region 50 preferably does not include the pair of first connection regions 54B.

According to this structure, a formation region of each first region 51 can be reduced and a crystal defect with the first region 51 as a starting point can be suppressed. Also, according to this structure, the a-plane defect with the first region 51 as the starting point can be suppressed in the regions between the second trench structures 20 and the third trench structures 30B (regions extending along a-planes of the SiC monocrystal). Such a structure is therefore effective in terms of suppressing the increase in the resistance value (the on resistance) due to the a-plane defect.

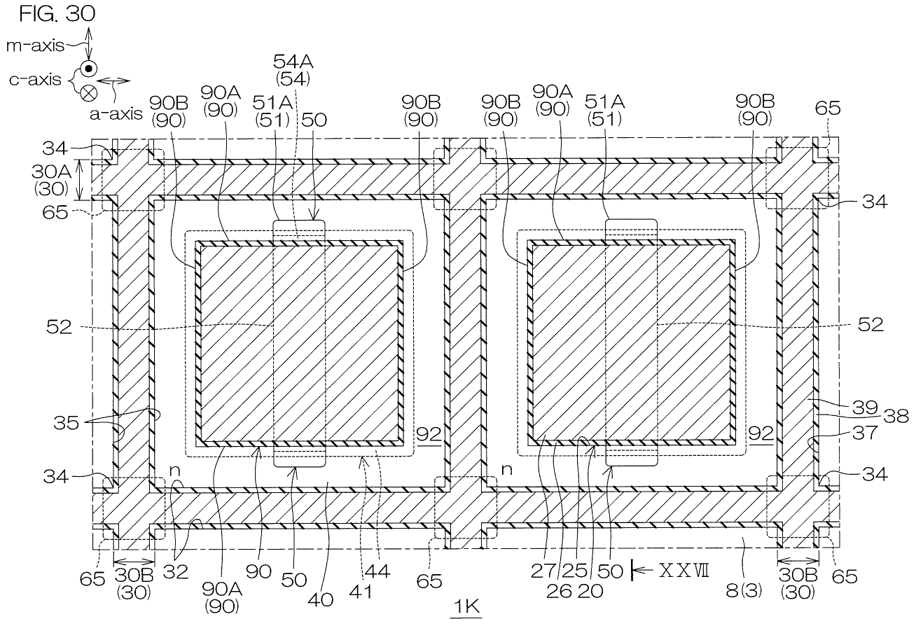

FIG. 30 is a plan view corresponding to FIG. 25 and showing an SiC semiconductor device 1K according to an eleventh embodiment. The SiC semiconductor device 1K has a mode in which the contact regions 50 of the SiC semiconductor device 1J are modified and is a device that exhibits the same effects as the SiC semiconductor device 1I. Specifically, each contact region 50 of the SiC semiconductor device 1K includes the second region 52 extending in a band shape in the m-axis direction at intervals in the a-axis direction from the pair of second side walls 90B.

The second region 52 extends in the band shape in the m-axis direction in a region between the pair of first regions 51A. A distance between the third trench structure 30B and the second region 52 is greater than a distance between the third trench structure 30A and the second region 52. The pair of first connection regions 54A described above connect the second region 52 to the pair of first regions 51A. The contact region 50 is thereby formed in a band shape extending in the m-axis direction at intervals in the a-axis direction from the pair of second side walls 90B in plan view.

According to this structure, the formation region of the second region 52 can be reduced and the crystal defect with the second region 52 as the starting point can be suppressed. Also, according to this structure, the a-plane defect with the second region 52 as the starting point can be suppressed in the regions between the second trench structures 20 and the third trench structures 30B (regions extending along a-planes of the SiC monocrystal). Such a structure is therefore effective in terms of suppressing the increase in the resistance value (the on resistance) due to the a-plane defect.

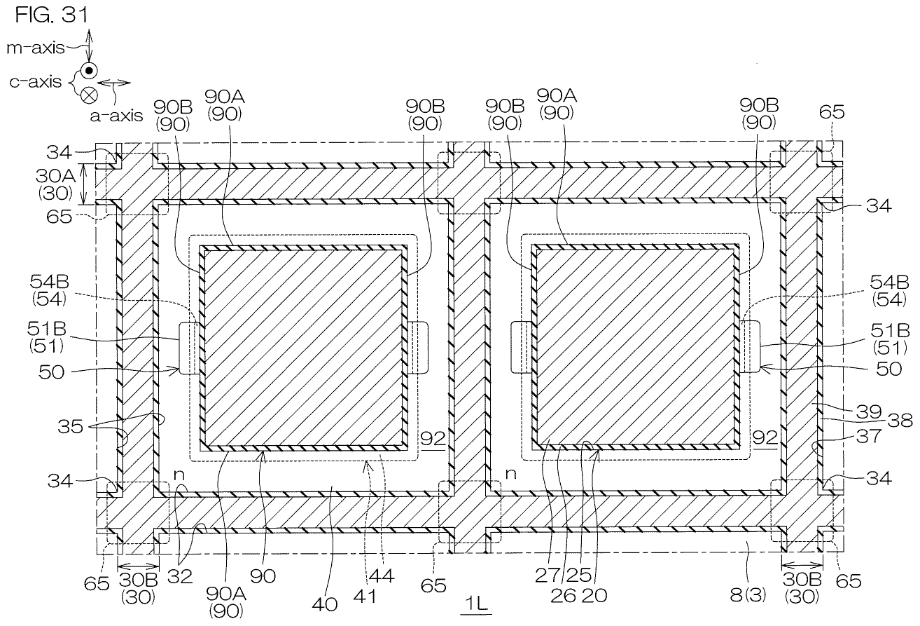

FIG. 31 is a plan view corresponding to FIG. 25 and showing an SiC semiconductor device 1L according to a twelfth embodiment. The SiC semiconductor device 1L is a device that exhibits the same effects as the SiC semiconductor device 1I. The SiC semiconductor device 1I described above includes the contact regions 50 each having the pair of first regions 51A and the pair of first regions 51B. On the other hand, each contact region 50 of the SiC semiconductor device 1L does not include the pair of first regions 51A. In this case, the contact region 50 preferably does not include the pair of first connection regions 54A.

According to this structure, the formation region of each first region 51 can be reduced and the crystal defect with the first region 51 as the starting point can be suppressed. Also, according to this structure, the m-plane defect with the first region 51 as the starting point can be suppressed in the regions between the second trench structures 20 and the third trench structures 30A (regions extending along m-planes of the SiC monocrystal). Such a structure is therefore effective in terms of suppressing the increase in the resistance value (the on resistance) due to the m-plane defect.

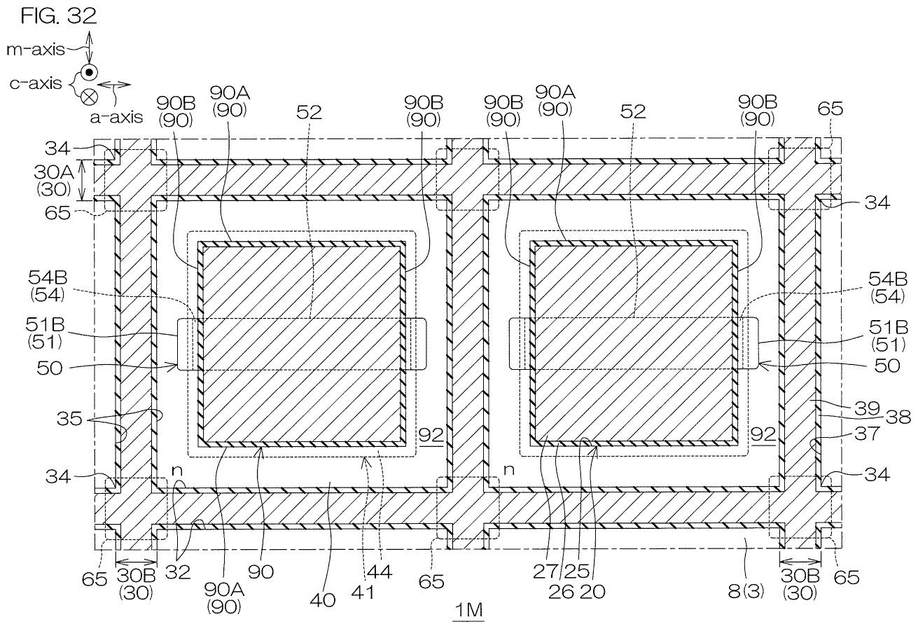

FIG. 32 is a plan view corresponding to FIG. 25 and showing an SiC semiconductor device 1M according to a thirteenth embodiment. The SiC semiconductor device 1M has a mode in which the contact regions 50 of the SiC semiconductor device 1L are modified and is a device that exhibits the same effects as the SiC semiconductor device 1I. Specifically, each contact region 50 of the SiC semiconductor device 1M includes the second region 52 extending in a band shape in the a-axis direction at intervals in the m-axis direction from the pair of first side walls 90A.

The second region 52 extends in the band shape in the a-axis direction in a region between the pair of first regions 51B. A distance between the third trench structure 30A and the second region 52 is greater than a distance between the third trench structure 30B and the second region 52. The pair of first connection regions 54B described above connect the second region 52 to the pair of first regions 51B. The contact region 50 is thereby formed in a band shape extending in the a-axis direction at intervals in the m-axis direction from the pair of first side walls 90A in plan view.

According to this structure, the formation region of the second region 52 can be reduced and the crystal defect with the second region 52 as the starting point can be suppressed. Also, according to this structure, the m-plane defect with the second region 52 as the starting point can be suppressed in the regions between the second trench structures 20 and the third trench structures 30A (regions extending along m-planes of the SiC monocrystal). Such a structure is therefore effective in terms of suppressing the increase in the leak current (the zero gate voltage drain current IDSS) due to the m-plane defect.

The contact regions 50 of the SiC semiconductor device 1M may be formed at the same time as the contact regions 50 of the SiC semiconductor device 1K. In this case, the contact regions 50 each of cross shape having a portion extending in a band shape in the a-axis direction and a portion extending in a band shape in the m-axis direction in plan view are formed.

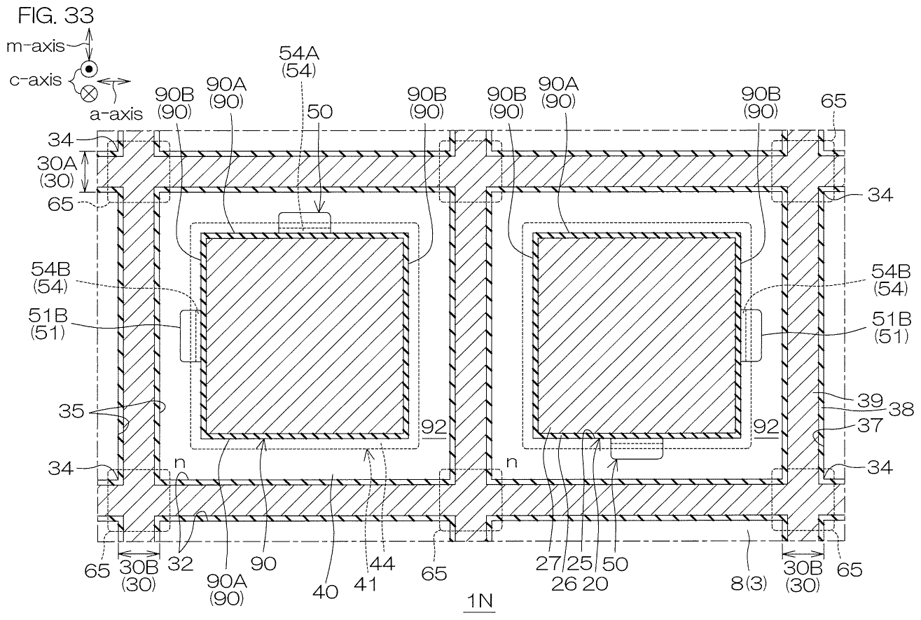

FIG. 33 is a plan view corresponding to FIG. 25 and showing an SiC semiconductor device 1N according to a fourteenth embodiment. The SiC semiconductor device 1N is a device that exhibits the same effects as the SiC semiconductor device 1I. The SiC semiconductor device 1I described above includes the contact regions 50 each having the pair of first regions 51A and the pair of first regions 51B.

On the other hand, each contact region 50 of the SiC semiconductor device 1N includes the single first region 51A and the single first region 51B. In correspondence to the single first region 51A and the single first region 51B, the contact region 50 includes the single first connection region 54A and the single first connection region 54B.

The single first connection region 54A connects the first region 51A and the second region 52. The single first connection region 54B connects the first region 51B and the second region 52. In this embodiment, the second region 52 covers the whole region of the bottom wall 91 of the second trench structure 20. As a matter of course, the second region 52 may extend in an L-shape between the first region 51A and the single first region 51B in plan view instead.

Looking at one second trench structure 20 and another second structure 20, a formation location of the first region 51A with respect to the one second structure 20 may be the same as or may differ from the formation location of the first region 51A with respect to the other second structure 20. Also, looking at the one second trench structure 20 and the other second structure 20, a formation location of the first region 51B with respect to the one second structure 20 may be the same as or may differ from the formation location of the first region 51B with respect to the other second structure 20.

According to this structure, them-plane defect and the a-plane defect each with the first region 51 as the starting point can be suppressed. Such a structure is effective in terms of suppressing the increase in the resistance value (the on resistance) due to the a-plane defect and suppressing the increase in the leak current (the zero gate voltage drain current IDSS) due to the m-plane defect.

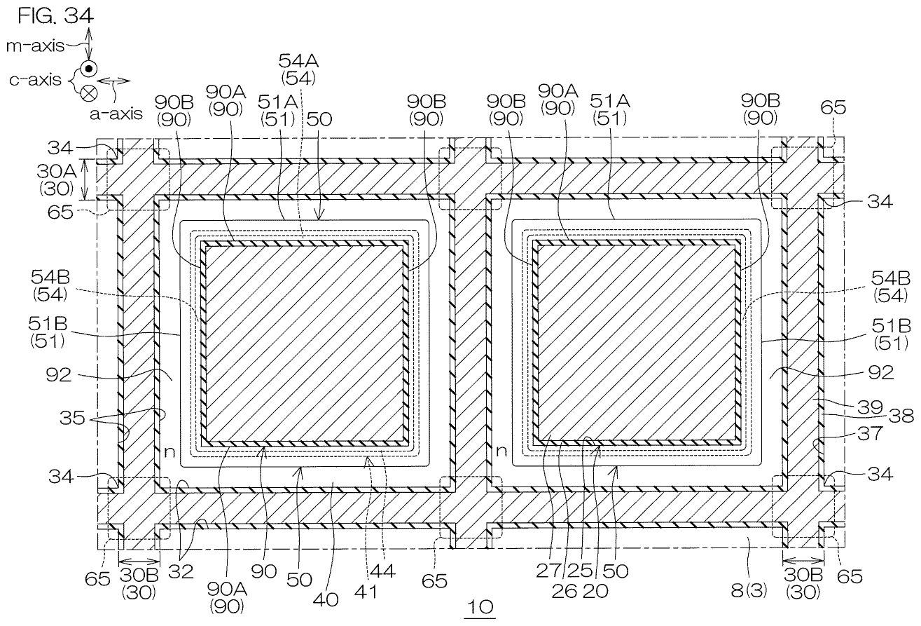

FIG. 34 is a plan view corresponding to FIG. 25 and showing an SiC semiconductor device 1O according to a fifteenth embodiment. The SiC semiconductor device 1O is a device that exhibits the same effects as the SiC semiconductor device 1I. The SiC semiconductor device 1I described above includes the pair of first regions 51A that are formed in regions along portions of the pair of first side walls 90A and the pair of first regions 51B that are formed in regions along portions of the pair of second side walls 90B.

On the other hand, the SiC semiconductor device 1O includes the pair of first regions 51A that are formed in regions along whole regions of the pair of first side walls 90A and the pair of first regions 51B that are formed in regions along whole regions of the pair of second side walls 90B. That is, in this embodiment, each contact region 50 includes the single first region 51 that surrounds the side wall 90 of the second trench structure 20.

Also, the contact region 50 may include the pair of first connection regions 54A that are formed in regions along the whole regions of the pair of first side walls 90A and the pair of first connection regions 54B that are formed in regions along the whole regions of the pair of second side walls 90B. That is, the contact region 50 may include the single first connection region 54 that is formed in a region along the whole region of the side wall 90.

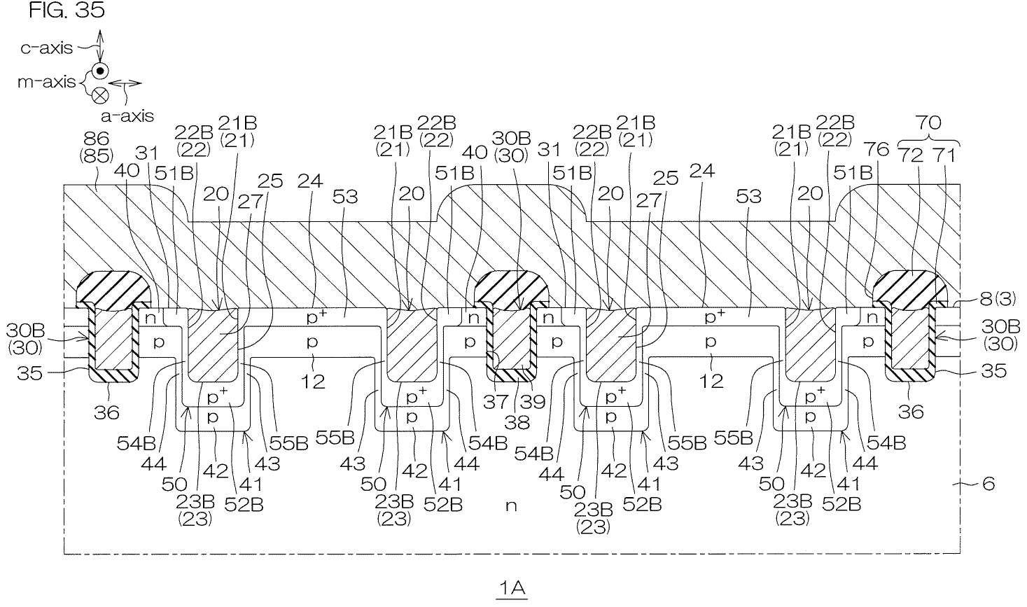

FIG. 35 is a cross sectional view showing a modification example of the second trench structures 20. Although an example in which the second trench structures 20 of the modification example are applied to the SiC semiconductor device 1A according to the first embodiment is shown in FIG. 35, the second trench structures 20 of the modification example may be applied to the SiC semiconductor devices 1B to 1O according to the second to fifteenth embodiments.

The second trench structures 20 of the respective embodiments described above each include the second trench 25, the second insulating film 26, and the second embedded electrode 27. On the other hand, the second trench structures 20 according to the modification example do not include the second insulating film 26. The second embedded electrode 27 is directly embedded in the second trench 25 and is electrically and mechanically connected to the chip 2 inside the second trench 25.

The source region 40, the well region 41, and the contact region 50 described above are electrically and mechanically connected to the second embedded electrode 27 at a portion along the wall surfaces (inner side wall 21, outer side wall 22, and bottom wall 23) of each second trench structure 20.

The second embedded electrodes 27 may each be formed using a portion of the source electrode 85 (source pad electrode 86). That is, the source electrode 85 (source pad electrode 86) may be formed such as to enter into the plurality of second trenches 25 from above the main surface insulating film 70 (active surface 8). In this case, the source electrode 85 (source pad electrode 86) includes a plurality of second embedded electrodes 27 that are electrically and mechanically connected to the chip 2 inside the plurality of second trenches 25.

Each of the embodiments described above can be implemented in yet other modes. With each of the embodiments described above, an example in which the second semiconductor region 7 is formed inside the chip 2 was illustrated. However, a structure not having the second semiconductor region 7 may be adopted. In this case, the first semiconductor region 6 is exposed from the first main surface 3, the second main surface 4, and the first to fourth side surfaces 5A to 5D of the chip 2. That is, the chip 2 may have a single layer structure not having an SiC substrate and consisting of just an SiC epitaxial layer.

In each of the embodiments described above, the regions of the “n-type” may be replaced with regions of the “p-type” at the same time as replacing the regions of the “p-type” with regions of the “n-type.” A specific configuration in this case can be obtained by replacing the “n-type” with the “p-type” at the same time as replacing the “p-type” with the “n-type” in the above descriptions and attached drawings. If the “p-type” is referred to as a “first conductivity type,” the “n-type” may be referred to as a “second conductivity type.” If the “n-type” is referred to as the “first conductivity type,” the “p-type” may be referred to as the “second conductivity type.”

With each of the embodiments described above, the second semiconductor region 7 of the “n-type” has been illustrated. However, the second semiconductor region 7 of the “p-type” may be adopted instead. In this case, an SiC-IGBT (insulated gate bipolar transistor) is formed instead of the SiC-MISFET. In this case, in the above description, the “source” of the MISFET is replaced with an “emitter” of the IGBT, and the “drain” of the MISFET is replaced with a “collector” of the IGBT. The second semiconductor region 7 of the “p-type” may consist of an SiC substrate of the “p-type” or may be formed by introducing a p-type impurity into a surface layer portion of the second main surface 4 of the chip 2 (epitaxial layer) by an ion implantation method.

Hereinafter, examples of features extracted from the present description and the attached drawings shall be indicated below. Hereinafter, the alphanumeric characters, etc., in parentheses represent the corresponding components, etc., in the embodiments described above, but are not intended to limit the scope of each clause to the embodiments. The “SiC semiconductor device” in the following clauses may be replaced with a “semiconductor device,” an “SiC semiconductor switching device,” or an “SiC-MISFET” as needed.

[A1] An SiC semiconductor device (1A to 1O) comprising: a chip (2) that includes an SiC monocrystal and has a main surface (3); a trench structure (20) that has a side wall (21, 22, 90) and a bottom wall (23, 91) and is formed in the main surface (3); and a contact region (50) of a first conductivity type (p-type) that includes a first region (51, 53) formed in a region in a surface layer portion of the main surface (3) along the side wall (21, 22, 90) and a second region (52) formed in a region inside the chip (2) along the bottom wall (23, 91) and having an impurity concentration lower than an impurity concentration of the first region (51, 53).

[A2] The SiC semiconductor device (1A to 1O) according to A1, wherein a source potential is to be applied to the trench structure (20).

[A3] The SiC semiconductor device (1A to 1O) according to A1 or A2, wherein the first region (51, 53) includes a high concentration region (51H, 53H) that is positioned at the main surface (3) side and a low concentration region (51L, 53L) that has an impurity concentration lower than an impurity concentration of the high concentration region (51H, 53H) and is positioned at a bottom portion side and the second region (52) has the impurity concentration lower than the impurity concentration of the high concentration region (51H, 53H).

[A4] The SiC semiconductor device (1A to 1O) according to any one of A1 to A3, further comprising: a body region (12) of the first conductivity type (p-type) that is formed in the surface layer portion of the main surface (3); and wherein the trench structure (20) is formed in the main surface (3) such as to penetrate through the body region (12), the first region (51, 53) has the impurity concentration higher than an impurity concentration of the body region (12) and is formed in a surface layer portion of the body region (12), and the second region (52) has the impurity concentration higher than the impurity concentration of the body region (12).

[A5] The SiC semiconductor device (1A to 1O) according to any one of A1 to A4, further comprising: a well region (41) of the first conductivity type (p-type) that is formed in a region inside the chip (2) along the bottom wall (23, 91); and wherein the first region (51, 53) has the impurity concentration higher than an impurity concentration of the well region (41) and the second region (52) has the impurity concentration higher than the impurity concentration of the well region (41) and is formed in a region inside the well region (41) along the bottom wall (23, 91).

[A6] The SiC semiconductor device (1A to 1O) according to any one of A1 to A5, wherein the contact region (50) further includes a connection region (54, 55) that is formed in a region inside the chip (2) along the side wall (21, 22, 90) such as to connect the first region (51, 53) and the second region (52).

[A7] The SiC semiconductor device (1A to 1O) according to A6, wherein the connection region (54, 55) has an impurity concentration lower than the impurity concentration of the first region (51, 53).

[A8] The SiC semiconductor device (1A to 1O) according to A6 or A7, wherein a thickness of the connection region (54, 55) on a basis of the side wall (21, 22, 90) is less than a thickness of the first region (51, 53) on a basis of the main surface (3).

[A9] The SiC semiconductor device (1A to 1O) according to any one of A6 to A8, wherein a thickness of the connection region (54, 55) on a basis of the side wall (21, 22, 90) is less than a thickness of the second region (52) on a basis of the bottom wall (23, 91).

[A10] The SiC semiconductor device (1A to 1O) according to any one of A1 to A9, wherein the chip (2) includes the SiC monocrystal that consists of a hexagonal crystal and the side wall (21, 22, 90) includes a first side wall (21A, 22A, 90A) extending in an a-axis direction of the SiC monocrystal and a second side wall (21B, 22B, 90B) extending in an m-axis direction of the SiC monocrystal.

[A11] The SiC semiconductor device (1A to 1O) according to A10, wherein the first region (51, 53) is formed in a region along the first side wall (21A, 22A, 90A).

[A12] The SiC semiconductor device (1A to 1O) according to A11, wherein the first region (51, 53) is formed in the region along the first side wall (21A, 22A, 90A) at an interval in the a-axis direction from the second side wall (21B, 22B, 90B).

[A13] The SiC semiconductor device (1A to 1O) according to any one of A10 to A12, wherein at least one first region (51, 53) is formed in a region along the second side wall (21B, 22B, 90B).

[A14] The SiC semiconductor device (1A to 1O) according to A13, wherein the first region (51, 53) is formed in the region along the second side wall (21B, 22B, 90B) at an interval in the m-axis direction from the first side wall (21A, 22A, 90A).

[A15] The SiC semiconductor device (1A to 1O) according to any one of A1 to A14, further comprising: a second trench structure (30) that is formed in the main surface (3) at an interval from the trench structure (20) and to which a gate potential is to be applied.

[A16] The SiC semiconductor device (1A to 1O) according to A15, wherein the first region (51, 53) is formed at an interval to the trench structure (20) side from the second trench structure (30).

[A17] The SiC semiconductor device (1A to 1O) according to A15 or A16, wherein the second trench structure (30) is formed in an annular shape surrounding the trench structure (20) in plan view.

[A18] The SiC semiconductor device (1A to 1O) according to any one of A15 to A17, further comprising: a source region of a second conductivity type that is formed in a region in the surface layer portion of the main surface (3) along the second trench structure (30).

[A19] The SiC semiconductor device (1A to 1O) according to A18, wherein the first region (51, 53) is connected to the source region.

[A20] An SiC semiconductor device (1A to 1O) comprising: a chip (2) that includes an SiC monocrystal and has a main surface (3); a semiconductor region (6) of a first conductivity type (n-type) that is formed in a surface layer portion of the main surface (3); a body region (12) of a second conductivity type (p-type) that is formed in a surface layer portion of the semiconductor region (6); a trench source structure (20) that has a side wall (21, 22, 90) and a bottom wall (23, 91) and is formed in the main surface (3) such as to penetrate through the body region (12); a trench gate structure (30) that is formed in the main surface (3) at an interval from the trench source structure (20) such as to penetrate through the body region (12); a source region of the first conductivity type (n-type) that is formed in a region in a surface layer portion of the body region (12) along the trench gate structure (30); and a contact region (50) of the second conductivity type (p-type) that includes a first region (51, 53) formed in a region in the surface layer portion of the body region (12) along the side wall (21, 22, 90) of the trench source structure (20) and a second region (52) formed in a region inside the chip (2) along the bottom wall (23, 91) of the trench source structure (20) and having an impurity concentration lower than an impurity concentration of the first region (51, 53).

While embodiments of the present invention have been described in detail above, those are merely specific examples used to clarify the technical contents. The various technical ideas extracted from this Description are not limited by the order of description, the order of the embodiments, etc., in the Description and can be combined as appropriate with each other.

1. An SiC semiconductor device comprising:
a chip that includes an SiC monocrystal and has a main surface;
a trench structure that has a side wall and a bottom wall and is formed in the main surface; and
a contact region of a first conductivity type that includes a first region formed in a region along the side wall in a surface layer portion of the main surface and a second region formed in a region along the bottom wall inside the chip and having an impurity concentration lower than an impurity concentration of the first region.

2. The SiC semiconductor device according to claim 1,
wherein a source potential is to be applied to the trench structure.

3. The SiC semiconductor device according to claim 1,
wherein the first region includes a high concentration region that is positioned at the main surface side and a low concentration region that has an impurity concentration lower than an impurity concentration of the high concentration region and is positioned at a bottom portion side, and
the second region has the impurity concentration lower than the impurity concentration of the high concentration region.

4. The SiC semiconductor device according to claim 1, further comprising:
a body region of the first conductivity type that is formed in the surface layer portion of the main surface; and
wherein the trench structure is formed in the main surface such as to penetrate through the body region,
the first region has the impurity concentration higher than an impurity concentration of the body region and is formed in a surface layer portion of the body region, and
the second region has the impurity concentration higher than the impurity concentration of the body region.

5. The SiC semiconductor device according to claim 1, further comprising:
a well region of the first conductivity type that is formed in a region along the bottom wall inside the chip; and
wherein the first region has the impurity concentration higher than an impurity concentration of the well region, and
the second region has the impurity concentration higher than the impurity concentration of the well region and is formed in a region along the bottom wall inside the well region.

6. The SiC semiconductor device according to claim 1,
wherein the contact region further includes a connection region that is formed in a region along the side wall inside the chip such as to connect the first region and the second region.

7. The SiC semiconductor device according to claim 6,
wherein the connection region has an impurity concentration lower than the impurity concentration of the first region.

8. The SiC semiconductor device according to claim 6,
wherein a thickness of the connection region on a basis of the side wall is less than a thickness of the first region on a basis of the main surface.

9. The SiC semiconductor device according to claim 6,
wherein a thickness of the connection region on a basis of the side wall is less than a thickness of the second region on a basis of the bottom wall.

10. The SiC semiconductor device according to claim 1,
wherein the chip includes the SiC monocrystal that consists of a hexagonal crystal, and
the side wall includes a first side wall extending in an a-axis direction of the SiC monocrystal and a second side wall extending in an m-axis direction of the SiC monocrystal.

11. The SiC semiconductor device according to claim 10,
wherein the first region is formed in a region along the first side wall.

12. The SiC semiconductor device according to claim 11,
wherein the first region is formed in the region along the first side wall at an interval in the a-axis direction from the second side wall.

13. The SiC semiconductor device according to claim 10,
wherein the first region is formed in a region along the second side wall.

14. The SiC semiconductor device according to claim 13,
wherein the first region is formed in the region along the second side wall at an interval in the m-axis direction from the first side wall.

15. The SiC semiconductor device according to claim 1, further comprising:
a second trench structure that is formed in the main surface at an interval from the trench structure and to which a gate potential is to be applied.

16. The SiC semiconductor device according to claim 15,
wherein the first region is formed at an interval to the trench structure side from the second trench structure.

17. The SiC semiconductor device according to claim 15,
wherein the second trench structure is formed in an annular shape surrounding the trench structure in plan view.

18. The SiC semiconductor device according to claim 15, further comprising:
a source region of a second conductivity type that is formed in a region along the second trench structure in the surface layer portion of the main surface.

19. The SiC semiconductor device according to claim 18,
wherein the first region is connected to the source region.

20. An SiC semiconductor device comprising:
a chip that includes an SiC monocrystal and has a main surface;
a semiconductor region of a first conductivity type that is formed in a surface layer portion of the main surface;
a body region of a second conductivity type that is formed in a surface layer portion of the semiconductor region;
a trench source structure that has a side wall and a bottom wall and is formed in the main surface such as to penetrate through the body region;
a trench gate structure that is formed in the main surface at an interval from the trench source structure such as to penetrate through the body region;
a source region of the first conductivity type that is formed in a region along the trench gate structure in a surface layer portion of the body region; and
a contact region of the second conductivity type that includes a first region formed in a region along the side wall of the trench source structure in the surface layer portion of the body region and a second region formed in a region along the bottom wall of the trench source structure inside the chip and having an impurity concentration lower than an impurity concentration of the first region.
